(19) United States
(12) Patent Application Publication
(10) Pub. No.: US 2009/0200635 A1
(43) Pub. Date: Aug. 13, 2009

(54) Integrated Circuit Having Electrical Isolation Regions, Mask Technology and Method of Manufacturing Same

(76) Inventor: Viktor Koldiaev, San Jose, CA (US)

Correspondence Address: NEIL STEINBERG, 2300 M STREET, N.W., Suite 800, WASHINGTON, DC, 20037, US

(21) Appl. No.: 12/368,333

(22) Filed: Feb. 10, 2009

Related U.S. Application Data
(60) Provisional application No. 61/065,485, filed on Feb. 12, 2008.

(51) Int. Cl. H01L 29/06; H01L 21/762; H01L 21/31

(52) U.S. Cl. 257/506; 438/424; 438/761; 257/E21.546; 257/E29.02; 257/E21.24

(57) ABSTRACT

An integrated circuit device (e.g., a logic or memory device) having a plurality of memory cells each including at least one transistor, wherein transistors of neighboring memory cells are separated by isolation regions. The isolation regions include a first liner layer, a barrier layer disposed on or over the first liner layer, wherein the barrier layer is less than 3 nanometers, and preferably between about 1 nanometer to about 2 nanometers in thickness. The isolation regions further include a second liner layer (comprising, e.g., a silicon nitride material), disposed on or over the barrier layer, and an electrical isolation material, disposed on or over the second liner layer. The barrier layer prohibits, minimizes, reduces, inhibits and/or retards diffusion of nitrogen atoms there through. Also disclosed are methods of manufacturing such integrated circuit devices as well as methods of manufacture of a mask for use in fabrication of integrated circuits, wherein the mask comprises depositing a pad layer, depositing a barrier layer on or over the pad layer wherein the barrier layer includes a thickness of about 1 nanometer to about 2 nanometers, and depositing a hard mask layer on or over the barrier layer which includes a silicon nitride material. The barrier layer prohibits, minimizes, reduces, inhibits and/or retards diffusion of nitrogen atoms there through.

### RELATED APPLICATION

This application claims priority to U.S. Provisional Application Ser. No. 61/065,485, entitled “Integrated Circuit Having Electrical Isolation Trenches, Mask Technology and Method of Manufacturing Same”, filed Feb. 12, 2008; the contents of this provisional application are incorporated by reference herein in their entirety.

### INTRODUCTION

The present inventions relate to a memory cell, array, architecture and device, and techniques for reading, controlling and/or operating such cell and device; and more particularly, in one aspect, to a semiconductor dynamic random access memory (“DRAM”) cell, array, architecture and/or device wherein the memory cell includes a transistor having an electrically floating body in which an electrical charge is stored.

There is a continuing trend to employ and/or fabricate advanced integrated circuits using techniques, materials and devices that improve performance, reduce leakage current and enhance overall scaling. Semiconductor-on-Insulator (SOI) is a material in which such devices may be fabricated or disposed on or in (hereinafter collectively “on”). Such devices are known as SOI devices and include, for example, partially depleted (PD), fully depleted (FD) devices, multiple gate devices (for example, double or triple gate), and Fin-FET.

One type of dynamic random access memory cell is based on, among other things, the electrically floating body effect of SOI transistors. (See, for example, U.S. Pat. No. 6,969,662, incorporated herein by reference). In this regard, the dynamic random access memory cell may consist of a PD or a FD SOI transistor (or transistor formed in bulk material/substrate) having a channel, which is interposed between the body and the gate dielectric. The body region of the transistor is electrically floating in view of the insulation layer (or non-conductive region, for example, in a bulk-type material/substrate) disposed beneath the body region. The state of memory cell is determined by the concentration or amount of charge within the body region of the SOI transistor.

With reference to FIGS. 1A, 1B and 1C, in one embodiment, semiconductor DRAM array 10 includes a plurality of memory cells 12 each consisting of an n-channel transistor 14 having gate 16 (typically an n+ doped polycrystalline silicon material), body region 18, which is electrically floating, source region 20 and drain region 22. The body region 18 is disposed between source region 20 and drain region 22. Moreover, body region 18 is disposed on or above region 24, which may be an insulation region (for example, in an SOI material/substrate) or non-conductive region (for example, in a bulk-type material/substrate). The insulation or non-conductive region 24 may be disposed on substrate 26.

Data is written into or read from a selected memory cell by applying suitable control signals to a selected word line(s) 28, a selected source line(s) 30 and/or a selected bit line(s) 32. In response, charge carriers are accumulated in or emitted and/or ejected from electrically floating body region 18 wherein the data states are defined by the amount of carriers within electrically floating body region 18. Notably, the entire contents of the '662 Patent, including, for example, the features, attributes, architectures, configurations, materials, techniques and advantages described and illustrated therein, are incorporated by reference herein.

As mentioned above, memory cell 12 of DRAM array 10 operates by accumulating in or emitting/ejecting majority carriers (electrons or holes) 34 from body region 18 of, for example, n-channel transistors. (See, FIGS. 2A and 2B). In this regard, accumulating majority carriers (in this example, “holes”) 34 in body region 18 of memory cells 12 via, for example, impact ionization near source region 20 and/or drain region 22, is representative of a logic high or “1” data state. (See, FIG. 2A). Emitting or ejecting majority carriers 34 from body region 18 via, for example, forward biasing the source/body junction and/or the drain/body junction, is representative of a logic low or “0” data state. (See, FIG. 2B).

Notably, for at least the purposes of this discussion, a logic high or State “1” corresponds to an increased concentration of majority carriers in the body region relative to an unprogrammed device and/or a device that is programmed with a logic low or State “0”. In contrast, a logic low or State “0” corresponds to a reduced concentration of majority carriers in the body region relative to an unprogrammed device and/or a device that is programmed with logic high or State “1”.

Conventional reading is performed by applying a small drain bias and a gate bias above the transistor threshold voltage The sensed drain current is determined by the charge stored in the floating body giving a possibility to distinguish between the states “1” and “0”. A floating body memory device has two different current states corresponding to the two different logical states: “1” and “0”.

In one conventional technique, the memory cell is read by applying a small bias to the drain of the transistor as well as a gate bias which is above the threshold voltage of the transistor. In this regard, in the context of memory cells employing n-type transistors, a positive voltage is applied to one or more word lines 28 to enable the reading of the memory cells associated with such word lines. The amount of drain current is determined/affected by the charge stored in the electrically floating body region of the transistor. As such, conventional reading techniques sense the amount of the channel current provided/generated in response to the application of a predetermined voltage on the gate of the transistor of the memory cell to determine the state of the memory cell; a floating body memory cell may have two or more different current states corresponding to two or more different logical states (for example, two different current conditions/states corresponding to the two different logical states: “1” and “0”).

In short, conventional writing programming techniques for memory cells having an n-channel type transistor often provide an excess of majority carriers by channel impact ionization (see, FIG. 3A) or by band-to-band tunneling (gate-induced drain leakage “GIDL”) (see, FIG. 3B). The majority carriers may be removed via drain side hole removal (see, FIG. 4A), source side hole removal (see, FIG. 4B), or drain and source hole removal, for example, using the back gate pulsing (see, FIG. 4C).

Further, FIG. 5 illustrates the conventional reading technique. In one embodiment, the state of the memory cell may be determined by sensing the amount of the channel current provided/generated in response to the application of a predetermined voltage on the gate of the transistor of the memory cell.

The memory cell 12 having electrically floating body transistor 14 may be programmed/read using other techniques including techniques that may, for example, provide lower power consumption relative to conventional techniques. For example, memory cell 12 may be programmed, read and/or controlled using the techniques and circuitry described and illustrated in Okhonin et al., U.S. Patent Application Publication No. 2007/0058427 (“Memo Cell and Memory Cell Array Having an Electrically Floating Body Transistor, and Methods of Operating Same”, U.S. Non-Provisional patent application Ser. No. 11/509,188, filed on Aug. 24, 2006 (hereinafter “the '188 Application”)), which is incorporated by reference herein. In one aspect, the '188 Application is directed to programming, reading and/or control methods which allow low power memory programming and provide larger memory programming window (both relative to at least the conventional programming techniques).

With reference to FIG. 6, in one embodiment, the '188 Application employs memory cell 12 having electrically floating body transistor 14. The electrically floating body transistor 14, in addition to the MOS transistor, includes an intrinsic bipolar transistor (including, under certain circumstances, a significant intrinsic bipolar current). In this illustrative exemplary embodiment, electrically floating body transistor 14 is an n-channel device having gate 16 (typically an n+ doped polycrystalline silicon material), body region 18, which is electrically floating, source region 20 and drain region 22, wherein the body region 18 is disposed between source region 20 and drain region 22. In an n-channel device, the majority carriers are “holes”.

With reference to FIG. 7, in one embodiment, the '188 Application employs, writes or programs a logic “1” or logic high using control signals (having predetermined voltages, for example, Vg=0V, Vs=3V, and Vd=0V) which are applied to gate 16, source region 20 and drain region 22 (respectively) of transistor 14 of memory cell 12. Such control signals induce or cause impact ionization and/or the avalanche multiplication phenomenon. (See, FIG. 7). The predetermined voltages of the control signals, in contrast to the conventional method program or write logic “1” in the transistor of the memory cell via impact ionization and/or avalanche multiplication in the electrically floating body. In one embodiment, it is preferred that the bipolar transistor current responsible for impact ionization and/or avalanche multiplication in the floating body is initiated and/or induced by a control pulse which is applied to gate 16. Such a pulse may induce the channel impact ionization which increases the floating body potential and turns on the bipolar current. An advantage of the described method is that larger amount of the excess majority carriers is generated compared to other techniques.

Further, with reference to FIG. 8, when writing or programming logic “0” in transistor 14 of memory cell 12, in one embodiment of the '188 Application, the control signals (having predetermined voltages (for example, Vg=0.5V, Vs=3V and Vd=0.5V) are different and, in at least one embodiment, higher than a holding voltage (if applicable)) are applied to gate 16, source region 20 and drain region 22 (respectively) of transistor 14 of memory cell 12. Such control signals induce or provide removal of majority carriers from the electrically floating body of transistor 14. In one embodiment, the majority carriers are removed, eliminated or ejected from body region 18 through source region 20 and drain region 22. (See, FIG. 8). In this embodiment, writing or programming memory cell 12 with logic “0” may again consume lower power relative to conventional techniques.

When memory cell 12 is implemented in a memory cell array configuration, it may be advantageous to implement a “holding” operation for certain memory cells 12 when programming one or more other memory cells 12 of the memory cell array to enhance the data retention characteristics of such certain memory cells 12. The transistor 14 of memory cell 12 may be placed in a “holding” state via application of control signals (having predetermined voltages) that are applied to gate 16 and source region 20 and drain region 22 of transistor 14 of memory cell 12. In combination, such control signals provide, cause and/or induce majority carrier accumulation in an area that is close to the interface between gate dielectric 16a and electrically floating body region 18. (See, FIG. 9). In this embodiment, it may be preferable to apply a negative voltage to gate 16 where transistor 14 is an n-channel type transistor.

With reference to FIG. 10, in one embodiment of the '188 Application, the data state of memory cell 12 may be read and/or determined by applying control signals (having predetermined voltages, for example, Vg=−0.5V, Vs=3V and Vd=0V) to gate 16 and source region 20 and drain region 22 of transistor 14. Such signals, in combination, induce and/or cause the bipolar transistor current in those memory cells 12 storing a logic state “1”. For those memory cells that are programmed to a logic state “0”, such control signals do not induce and/or cause a considerable, substantial or sufficiently measurable bipolar transistor current in the cells programmed to “0” state. (See, the '188 Application, which, as noted above, is incorporated by reference).

The reading may be performed using negative or positive voltages applied to word lines 28. As such, transistors 14 of device 10 are periodically pulsed between a positive gate bias, which (1) drives majority carriers (holes for n-channel transistors) away from the interface between gate insulator 32 and body region 18 of transistor 14 and (2) causes minority carriers (electrons for n-channel transistors) to flow from source region 20 and drain region 22 into a channel formed below gate 16, and the negative gate bias, which causes majority carriers (holes for n-channel transistors) to accumulate in or near the interface between gate 16 and body region 18 of transistor 14.

Notably, the illustrated/exemplary voltage levels to implement the write and read operations, with respect to the '188 Application are merely exemplary. The indicated voltage levels may be relative or absolute. Alternatively, the voltages indicated may be relative in that each voltage level, for example, may be increased or decreased by a given voltage amount (for example, each voltage may be increased or decreased by 0.25, 0.5, 1.0 and 2.0 volts) whether one or more of the voltages (for example, the source, drain or gate voltages) become or are positive and negative.

### SUMMARY OF CERTAIN ASPECTS OF THE INVENTIONS

There are many inventions described and illustrated herein. The present inventions are neither limited to any single aspect nor embodiment thereof, nor to any combinations and/or permutations of such aspects and/or embodiments. Moreover, each of the aspects of the present inventions, and/or embodiments thereof, may be employed alone or in combination with one or more of the other aspects of the present inventions and/or embodiments thereof. For the sake of brevity, many of those permutations and combinations will not be discussed separately herein.

In a first principle aspect, certain of the present inventions are directed to a method of manufacture of an integrated circuit device (for example, a logic or memory device) including a plurality of memory cells, wherein each memory cell thereof includes at least one transistor, wherein transistors of neighboring memory cells are separated by isolation regions, the method comprising depositing a first liner layer in a plurality of isolation trenches and depositing (using, for example, atomic layer deposition) a barrier layer on or over the first liner layer and in the isolation trenches, wherein the barrier layer includes a thickness of less than 3 nanometers. The method further includes depositing a second liner layer on or over the barrier layer and in the isolation trenches, wherein the second liner layer includes a nitrogen bearing material and wherein during deposition of the second liner layer, the barrier layer inhibits diffusion of nitrogen atoms there through. The method of this aspect of the inventions, may (in certain embodiments) also include depositing an electrical isolation material on or over the second liner layer and in the isolation trenches, wherein isolation regions are disposed between neighboring memory cells and comprise materials of the first liner layer, barrier layer, second liner layer and electrical isolation material.

In one embodiment, the barrier layer is a nitrogen bearing material. In one embodiment, the material of the barrier layer is deposited to a thickness of about 1 nanometer to about 2 nanometers. Indeed, in one embodiment, the barrier layer is a nitrogen bearing material which is deposited to a thickness of about 1 nanometer to about 2 nanometers.

In another embodiment, the barrier layer is a silicon bearing material, for example, an amorphous silicon material. Moreover, the deposition of the barrier layer may use nitrogen ion implantation.

In yet another embodiment of this aspect of the inventions, the depositing the first liner layer in the plurality of isolation trenches further includes depositing the material of the first liner layer to a thickness of about 3 nanometers to about 10 nanometers, depositing the barrier layer on or over the first liner layer further includes depositing the material of the barrier layer to a thickness of about 1 nanometer to about 2 nanometers, and depositing the second liner layer on or over the barrier layer further includes depositing the material of the second liner layer to a thickness of about 3 nanometers to about 10 nanometers. Indeed, in one embodiment, the first liner layer is a silicon oxide material, the barrier layer is a silicon nitride material having a thickness of less than 3 nanometers, and the second liner layer is a silicon nitride material.

In another principal aspect, the present inventions are directed to an integrated circuit device (for example, a logic or memory device) comprising isolation regions formed in an exposed surface of a material of or on a substrate and a plurality of memory cells. The isolation regions include a first liner layer, a barrier layer (comprised of, for example, a nitrogen or silicon bearing material) disposed on or over the first liner layer, wherein the barrier layer is less than 3 nanometers in thickness and inhibits diffusion of nitrogen atoms there through, and a second liner layer disposed on or over the barrier layer, wherein the second liner layer includes a nitrogen bearing material. The integrated circuit device may further include a plurality of memory cells, wherein each memory cell thereof includes at least one transistor, wherein transistors of neighboring memory cells are separated by the isolation regions.

Notably, in certain embodiments, the integrated circuit may include an electrical isolation material disposed on or over the second liner layer.

In one embodiment, the barrier layer is about 1 nanometer to about 2 nanometers in thickness. In another embodiment, the barrier layer is a nitrogen bearing material having a thickness of about 1 nanometer to about 2 nanometers. Indeed, in one embodiment, the barrier layer is an amorphous silicon material.

In another embodiment, the isolation regions includes a first liner layer which is about 3 nanometers to about 10 nanometers in thickness, a barrier layer which is about 1 nanometer to about 2 nanometers in thickness, and a second liner layer which is about 3 nanometers to about 10 nanometers in thickness. In another embodiment, the isolation regions include a first liner layer which is a silicon oxide material, a barrier layer which is a nitrogen bearing material having a thickness of about 1 nanometer to about 2 nanometers, and a second liner layer which is a silicon nitride material.

In yet another principal aspect, the present inventions are directed to a method of manufacture of a mask for use in fabrication of integrated circuits (for example, circuits of a logic or memory device) including a plurality of memory cells, wherein each memory cell thereof includes at least one transistor, wherein transistors of neighboring memory cells are separated by isolation regions. The method of manufacture of a mask comprises (i) depositing a pad layer on an exposed surface of a material of or on a substrate, (ii) depositing a barrier layer on or over the pad layer wherein the barrier layer includes a thickness of about 1 nanometer to about 2 nanometers, and (iii) depositing a hard mask layer on or over the barrier layer, wherein the hard mask layer includes a silicon nitride material and wherein the barrier layer inhibits diffusion of nitrogen atoms there through.

In one embodiment, the barrier layer includes a nitrogen bearing material. In another embodiment, the barrier layer includes a silicon bearing material, for example, an amorphous silicon material.

Again, there are many inventions, and aspects of the inventions, described and illustrated herein. This Summary is not exhaustive of the scope of the present inventions. Indeed, this Summary may not be reflective of or correlate to the inventions protected by the claims in this and/or in continuation/divisional applications hereof.

Moreover, this Summary is not intended to be limiting of the inventions or the claims (whether the currently presented claims or claims of a divisional/continuation application) and should not be interpreted in that manner. While certain embodiments have been described and/or outlined in this Summary, it should be understood that the present inventions are not limited to such embodiments, description and/or outline, nor are the claims limited in such a manner (which should also not be interpreted as being limited by this Summary).

Indeed, many other aspects, inventions and embodiments, which may be different from and/or similar to, the aspects, inventions and embodiments presented in this Summary, will be apparent from the description, illustrations and claims, which follow. In addition, although various features, attributes and advantages have been described in this Summary and/or are apparent in light thereof, it should be understood that such features, attributes and advantages are not required whether in one, some or all of the embodiments of the present inventions and, indeed, need not be present in any of the embodiments of the present inventions.

### BRIEF DESCRIPTION OF THE DRAWINGS

In the course of the detailed description to follow, reference will be made to the attached drawings. These drawings show different aspects of the present inventions and, where appropriate, reference numerals illustrating like structures, components, materials and/or elements in different figures are labeled similarly. It is understood that various combinations of the structures, components, materials and/or elements, other than those specifically shown, are contemplated and are within the scope of the present inventions.

Moreover, there are many inventions described and illustrated herein. The present inventions are neither limited to any single aspect nor embodiment thereof, nor to any combinations and/or permutations of such aspects and/or embodiments.

Moreover, each of the aspects of the present inventions, and/or embodiments thereof, may be employed alone or in combination with one or more of the other aspects of the present inventions and/or embodiments thereof. For the sake of brevity, many of those permutations and combinations will not be discussed and/or illustrated separately herein.

FIG. 1A is a schematic representation of a prior art DRAM array including a plurality of memory cells comprised of one electrically floating body transistor;

FIG. 1B is a three dimensional view of an exemplary prior art memory cell comprised of one electrically floating body transistor (PD-SOI NMOS);

FIG. 1C is a cross-sectional view of the prior art memory cell of FIG. 1B, cross-sectioned along line C-C′;

FIGS. 2A and 2B are exemplary schematic illustrations of the charge relationship, for a given data state, of the floating body, source and drain regions of a prior art memory cell comprised of one electrically floating body transistor (PD-SOI NMOS);

FIGS. 3A and 3B are exemplary schematic and general illustrations of conventional methods to program a memory cell to logic state “1” (i.e., generate or provide an excess of majority carrier in the electrically floating body of the transistor (an n-type channel transistor in this exemplary embodiment) of the memory cell of FIG. 1B; majority carriers in these exemplary embodiments are generated or provided by the channel electron impact ionization (FIG. 3A) and by GIDL or band to band tunneling (FIG. 3B));

FIGS. 4A-4C are exemplary schematics and general illustrations of conventional methods to program a memory cell to logic state “0” (i.e., provide relatively fewer majority carriers by removing majority carriers from the electrically floating body of the transistor of the memory cell of FIG. 1B; majority carriers may be removed through the drain region/terminal of the transistor (FIG. 4A), the source region/terminal of the transistor (FIG. 4B), and through both drain and source regions/terminals of the transistor by using, for example, the back gate pulses applied to the substrate/backside terminal of the transistor of the memory cell (FIG. 4C));

FIG. 5 illustrates an exemplary schematic (and control signal) of a conventional reading technique, the state of the memory cell may be determined by sensing the amount of the channel current provided/generated in response to the application of a predetermined voltage on the gate of the transistor of the memory cell;

FIG. 6 is a schematic representation of an equivalent electrically floating body memory cell (n-channel type) including an intrinsic bipolar transistor in addition to the MOS transistor;

FIG. 7 illustrates an exemplary schematic (and control signal voltage relationship) of an exemplary embodiment of an aspect of the '188 Application of programming a memory cell to logic state “1” by generating, storing and/or providing an excess of majority carriers in the electrically floating body of the transistor of the memory cell;

FIG. 8 illustrates an exemplary schematic (and control signals) of an exemplary embodiment of an aspect of the '188 Application of programming a memory cell to a logic state “0” by generating, storing and/or providing relatively fewer majority carriers (as compared to the number of majority carriers in the electrically floating body of the memory cell that is programmed to a logic state “1”) in the electrically floating body of the transistor of the memory cell, wherein the majority carriers are removed (write “0”) through both drain and source terminals by applying a control signal (for example, a programming pulse) to the gate of the transistor of the memory cell;

FIG. 9 illustrates an exemplary schematic (and control signals) of an exemplary embodiment of an aspect of the '188 Application of holding or maintaining the data state of a memory cell;

FIG. 10 illustrates an exemplary schematic (and control signals) of an exemplary embodiment of an aspect of the '188 Application of reading the data state of a memory cell by sensing the amount of the current provided/generated in response to an application of a predetermined voltage on the gate of the transistor of the memory cell;

FIG. 11 is a cross-sectional view of a mask (for example, hard mask) disposed on a semiconductor layer which is disposed on an insulation region (for example, in an SOI material/substrate) or a non-conductive region (for example, in a bulk-type material/substrate) which is disposed on, in or above a substrate, wherein the mask includes a pad layer, a barrier layer and a hard mask layer,

FIGS. 12A-12C illustrate cross-sectional views of the mask illustrated in FIG. 11 during fabrication thereof at various stages of an exemplary process to provide the mask, according to certain aspects of the present inventions;

FIG. 13 is a cross-sectional view of a trench isolation region (for example, shallow trench isolation (STI)) disposed in a semiconductor layer which is disposed on an insulation region (for example, in an SOI material/substrate) or a non-conductive region (for example, in a bulk-type material/substrate) which is disposed on, in or above a substrate, wherein the exemplary trench isolation region includes a first liner layer, a barrier layer, a second liner layer, and a thick isolation layer;

FIGS. 14A-14G illustrate cross-sectional views of the isolation trench region (for example, an isolation region disposed between adjacent transistors of, for example, a memory cell array) illustrated in FIG. 13 during fabrication thereof at various stages of an exemplary process to provide the isolation trench region in the semiconductor layer, according to certain aspects of the present inventions;

FIGS. 15A-15H illustrate cross-sectional views of the isolation trench region (for example, an isolation region disposed between adjacent transistors of, for example, a memory cell array) illustrated in FIG. 13 during fabrication thereof while employing the mask illustrated in FIG. 11 at various stages of an exemplary process to provide the isolation trench region in the semiconductor layer, according to certain aspects of the present inventions;

FIG. 16 is a cross-sectional view of an electrically floating body transistor of, for example, a memory cell of a plurality of memory cells (of, for example, a memory cell array), illustrating an exemplary embodiment of the isolation region of the present inventions according to at least one aspect of the present inventions;

FIG. 17 is a cross-sectional view of an electrically floating body transistor of, for example, a memory cell (of, for example, a memory cell array), wherein transistors include a pillar-type structure, illustrating an exemplary embodiment of the isolation region of the present inventions according to at least one aspect of the present inventions;

FIGS. 18A and 18B are cross-sectional views of a portion of an electrically floating body transistor (of, for example, a memory cell), illustrating an exemplary embodiment of the spacer regions of the present inventions according to at least one aspect of the present inventions, notably, FIG. 18A illustrates an over-lap of the source/drain regions in relation to the gate, and FIG. 18B illustrates an under-lap or non-overlap of the source/drain regions in relation to the gate (see, U.S. Patent Application Publication No. 2008/0180995);

FIGS. 19A and 19B are a three-dimensional view and a cross-sectional view (along line a-a′ of FIG. 19A), respectively, of an electrically floating body transistor (of, for example, a memory cell of, for example, a memory cell array), wherein transistors include a FinFET-type structure; and

FIGS. 20A-20C are block diagram illustrations of an exemplary devices in which the structures and/or processes may be implemented wherein FIG. 20A and 20C are logic devices (having logic circuitry and resident memory) and FIG. 20B is a memory device (having primarily of a memory array), according to certain aspects of the present inventions.

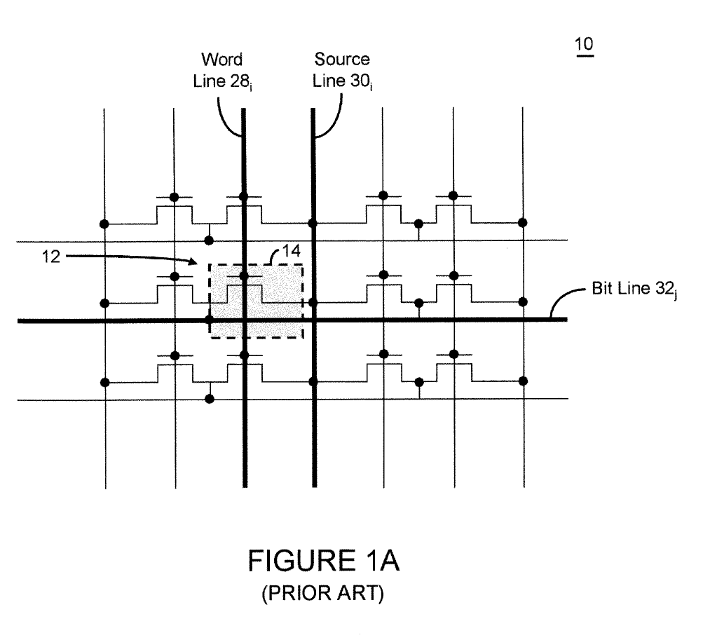

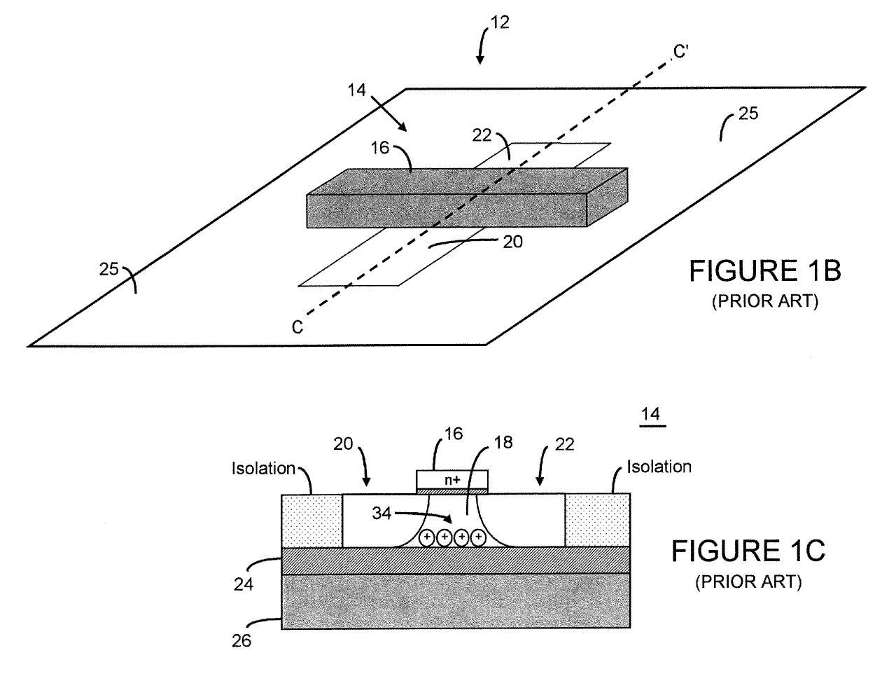

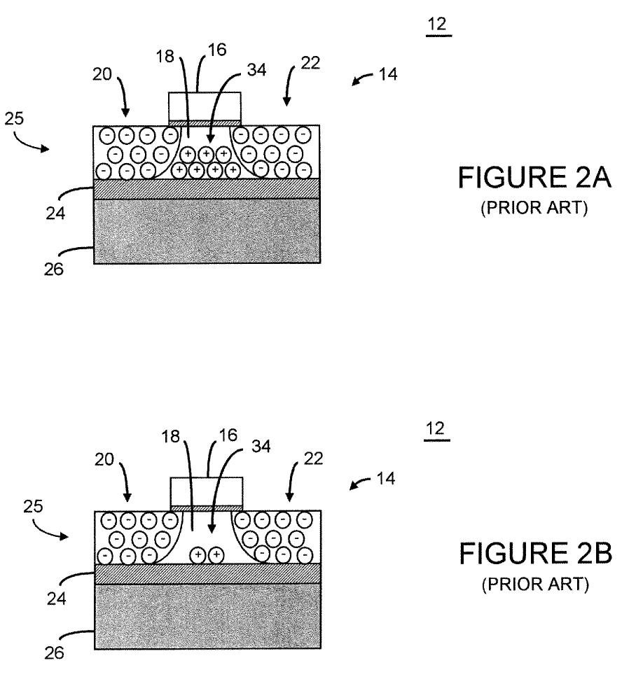

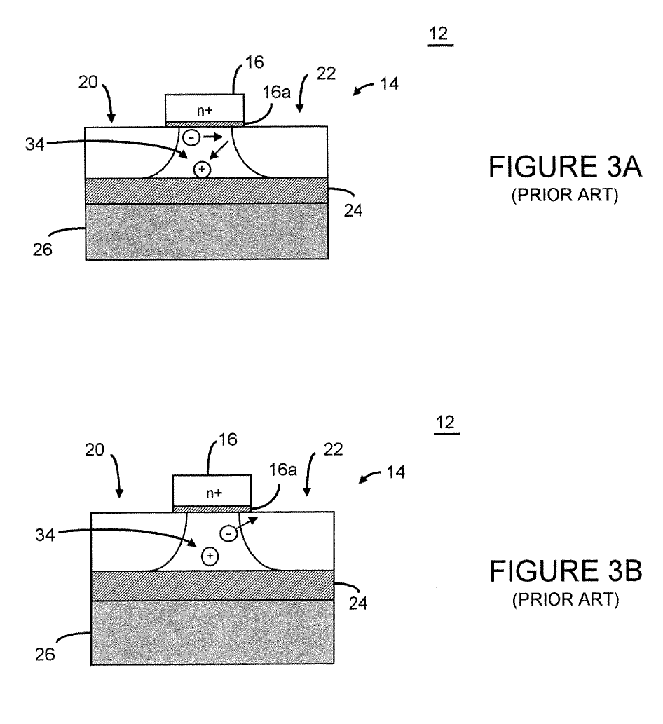

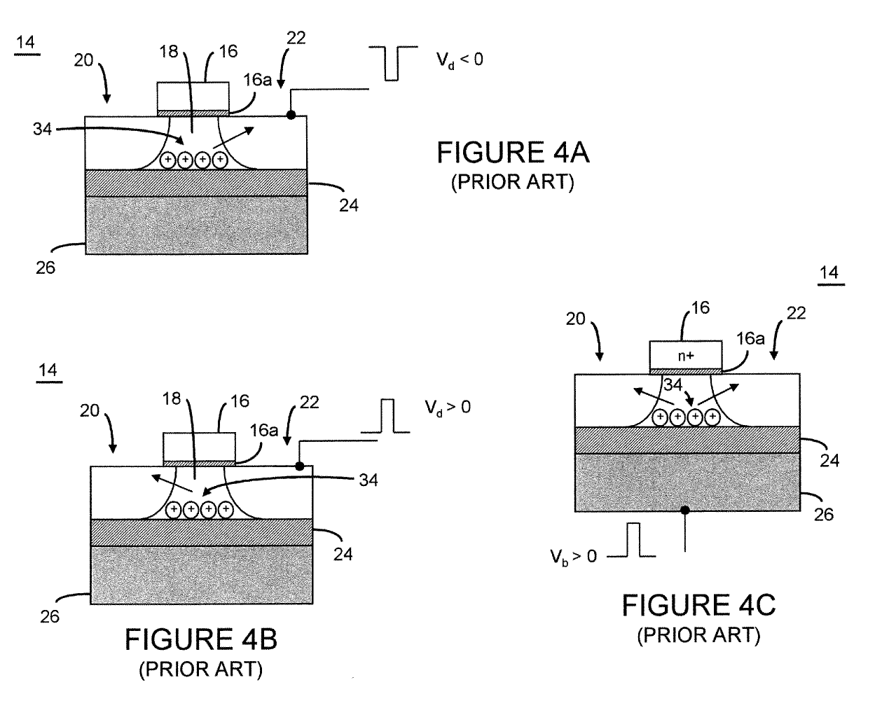

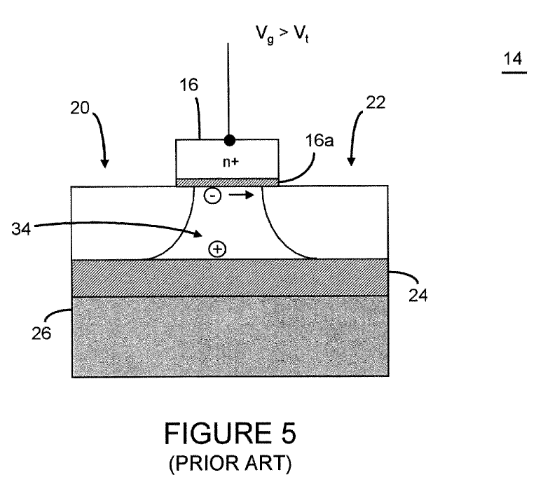

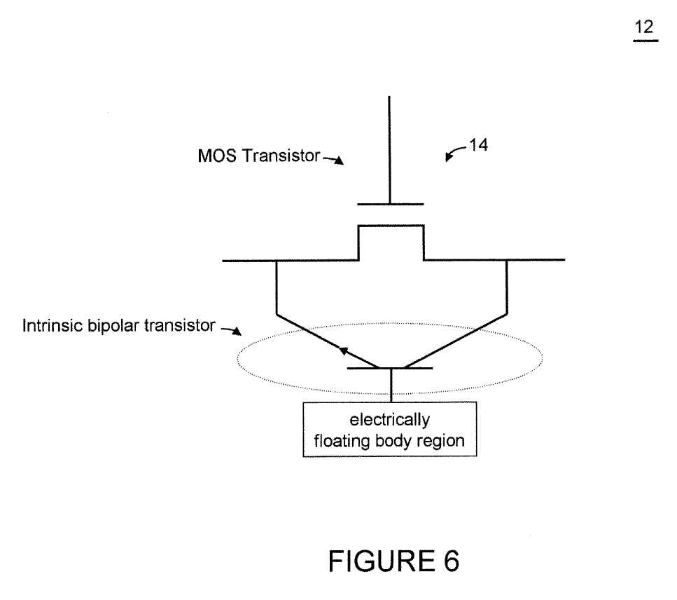

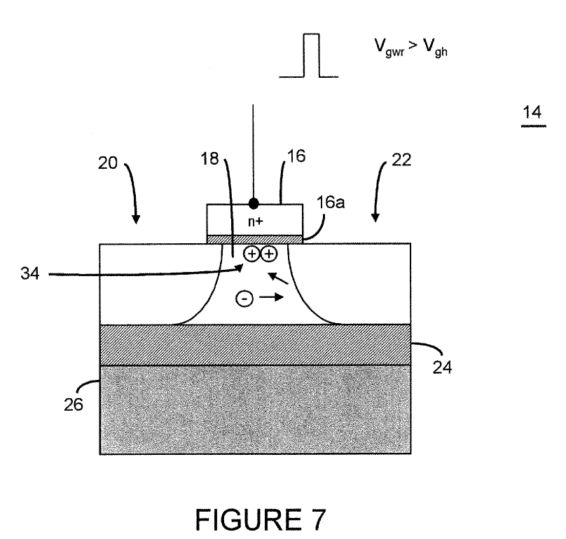

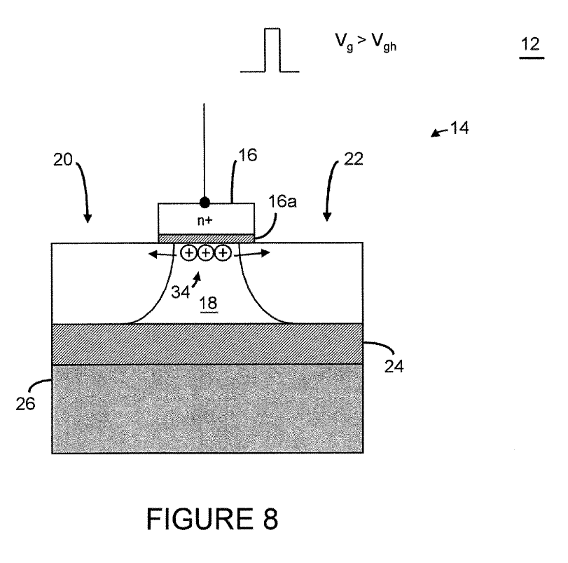

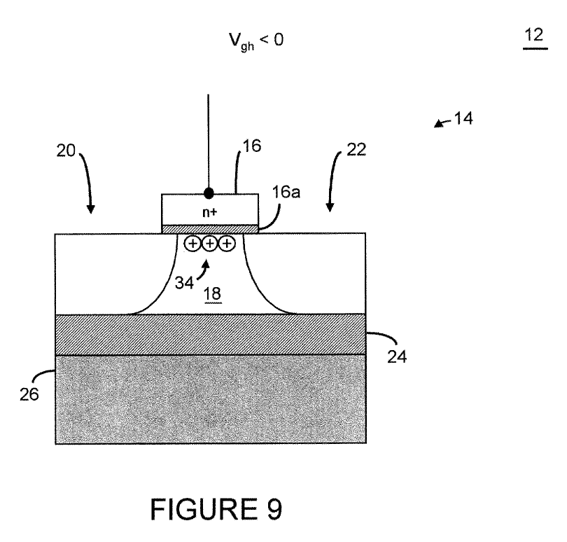

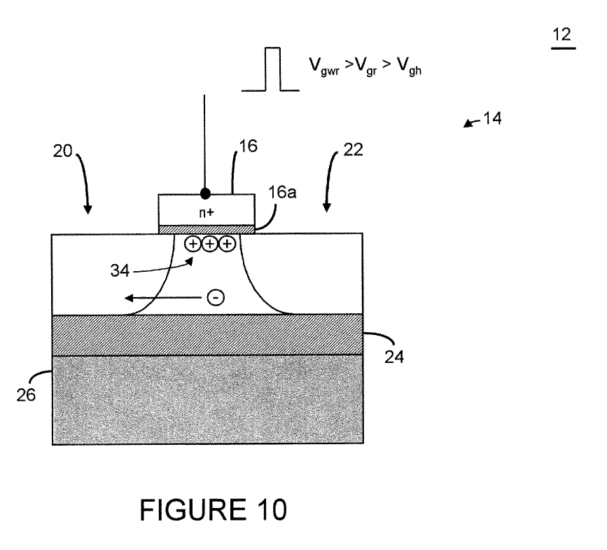

Again, there are many inventions described and illustrated herein. The present inventions are neither limited to any single aspect nor embodiment thereof, nor to any combinations and/or permutations of such aspects and/or embodiments. Each of the aspects of the present inventions, and/or embodiments thereof, may be employed alone or in combination with one or more of the other aspects of the present inventions and/or embodiments thereof. For the sake of brevity, many of those combinations and permutations are not discussed separately herein.

### DETAILED DESCRIPTION

There are many inventions described and illustrated herein. In one aspect, the present inventions are directed to a mask used in semiconductor processing, and a method of manufacturing such a mask. The mask of the present inventions includes a plurality of layers and/or materials (wherein one of the layers or materials is a relatively thin silicon nitride) which, in combination provides suitable or predetermined mask qualities as well as avoids, minimizes and/or eliminates nitridation of the material(s) or layer(s) underlying the mask. In this regard, in one embodiment, the mask includes a relatively thin silicon nitride (Si₃N₄) layer disposed between a pad layer (for example, a silicon oxide (SiO₂) layer) and a relatively thick nitrogen bearing material (for example, a silicon nitride). As such, when the mask is removed to facilitate subsequent processing/fabrication, such underlying material(s) or layer(s) are relatively free of nitride or compounds including nitride.

In another aspect, the present inventions are directed to an electrical isolation region and a method of manufacturing such a region. The electrical isolation region of the present inventions includes a plurality of layers and/or materials (wherein one of the layers or materials is a relatively thin barrier layer of, for example, a silicon nitride) which, in combination provides suitable or predetermined electrical isolation. In addition, the relatively thin silicon nitride layer may minimize, retard and/or prevent nitridation of the material or layer (for example, polycrystalline or monocrystalline silicon) adjacent to or in contact with the electrical isolation regions in those circumstances where the electrical isolation region includes a layer including a nitrogen bearing material (for example, silicon nitride).

Briefly, in conventional processes, during deposition and/or growth of a relatively thick silicon nitride, ammonia (NH₃) molecules may be captured by and/or penetrate into the surface of the underlying material(s), and diffuse through a conventional pad layer (for example, silicon oxide) to the interface of the layer underlying the pad layer (for example, polycrystalline or monocrystalline silicon—as such, the Si—SiO₂ interface). Such molecules may “nitridize” material at the interface of the layer underlying the conventional pad layer (for example, up to 3-10 atomic %)—thereby forming or creating a nitridation layer at the interface (for example, a SiON (nitridation) interfacial layer). Such nitridation of that interface may cause positive charge to migrate to and/or develop in the silicon oxide (“Qss”) and/or create, enhance and/or increase the concentration or density of the interface traps (“DIT”).

Where electrically floating body transistors, employed as memory cells, are to be formed in a given region, interface nitridation in that region that is greater than 1% may present an adverse or debilitating amount of positive charge in the silicon oxide and/or concentration or density of the interface traps. As such, it may be advantageous to minimize and/or reduce the positive charge in the silicon oxide and the concentration or density of the interface traps in those regions where memory cells comprising electrically floating body transistors are to be formed. Indeed, a relatively high Qss at or near the surface may cause the surface potential along the interface to be relatively high—resulting in or presenting a high electrical activity of interface traps (for example, whether intrinsic DIT and/or extrinsic DIT associated with contaminations) at or near the interface.

Moreover, a relatively high Qss may present a depletion layer within the material that is relatively thick thereby causing and/or enhancing a punch-through leakage current, for example, during the write operation (which may adversely affect or impact the write performance of the memory cell). In addition, a relatively high DIT may cause, provide and/or generate an adverse or debilitating leakage current thereby reducing and/or degrading the retention of the data state of the memory cell.

With that in mind, in one aspect, masks of the present inventions includes a plurality of layers and/or materials, wherein one of the layers or materials is a relatively thin silicon nitride, which, in combination provides suitable or predetermined mask qualities as well as avoids, minimizes and/or eliminates nitridation of the material(s) or layer(s) underlying the mask. The electrical isolation region of the present inventions includes a plurality of layers and/or materials, wherein one of the layers or materials includes a relatively thin silicon nitride, which provides suitable or predetermined electrical isolation and, in addition, may minimize, retard and/or prevent nitridation of the material or layer (for example, polycrystalline or monocrystalline silicon) adjacent to or in contact with the electrical isolation regions in those circumstances where the electrical isolation region includes a relatively thick nitrogen bearing material (for example, silicon nitride).

Notably, the present inventions may be implemented in conjunction with any memory cell technology, whether now known or later developed. For example, the memory cells may include one or more transistors having electrically floating body regions (for example, as described in detail in the Introduction), one transistor-one capacitor architectures, electrically floating gate transistors, junction field effect transistors (often referred to as JFETs), or any other memory/transistor technology whether now known or later developed. All such memory technologies are intended to fall within the scope of the present inventions.

Moreover, the present inventions may be implemented in conjunction with any type of memory (including discrete or integrated with logic devices), whether now known or later developed. For example, the memory may be a DRAM, SRAM and/or Flash. All such memories are intended to fall within the scope of the present inventions.

In one embodiment, the memory cell and/or memory cells of the memory cell array includes at least one transistor having an electrically floating body transistor which stores an electrical charge in the electrically floating body region thereof. The amount of charge stored in the in the electrically floating body region correlates to the data state of the memory cell. One type of such memory cell is based on, among other things, a floating body effect of semiconductor on insulator (SOI) transistors. (See, for example, (1) Fazan et al., U.S. Pat. No. 6,969,662, (2) Okhonin et al., U.S. Patent Application Publication No. 2006/0131650 (“Bipolar Reading Technique for a Memory Cell Having an Electrically Floating Body Transistor”), (3) Okhonin et al., U.S. Patent Application Publication No. 2007/0058427 (“Memory Cell and Memory Cell Array Having an Electrically Floating Body Transistor, and Methods of Operating Same”), (4) Okhonin, U.S. Patent Application Publication No. 2007/0138530 (“Electrically Floating Body Memory Cell and Array, and Method of Operating or Controlling Same”), (5) Okhonin et al., U.S. Patent Application Publication No. 2007/0187775, (“Multi-Bit Memory Cell Having Electrically Floating Body Transistor, and Method of Programming and Reading Same”), and (6) Okhonin, U.S. Patent Application Publication No. 2008/0180995, (“Semiconductor Device with Electrically Floating Body”), all of which are incorporated by reference herein in its entirety). In this regard, the memory cell may consist of a partially depleted (PD) or a fully depleted (FD) SOI transistor or bulk transistor (transistor which formed in or on a bulk material/substrate) having a gate, which is disposed adjacent to the electrically floating body and separated therefrom by a gate dielectric. The body region of the transistor is electrically floating in view of the insulation or non-conductive region, for example, in bulk-type material/substrate, disposed beneath the body region. The PD or FD SOI memory transistors made in the standard planar or any 3D technology may include a single gate or a plurality of gates (for example, FinFET, double gate (for example, planar or vertical type), or pillar gate architectures). The body region of the transistor is electrically floating in view of the insulation or non-conductive region, for example, in bulk-type material/substrate, disposed beneath and/or adjacent to the body region. The state of memory cell may be determined by, for example, the concentration or amount of charge contained or stored in the body region of the SOI or bulk transistor.

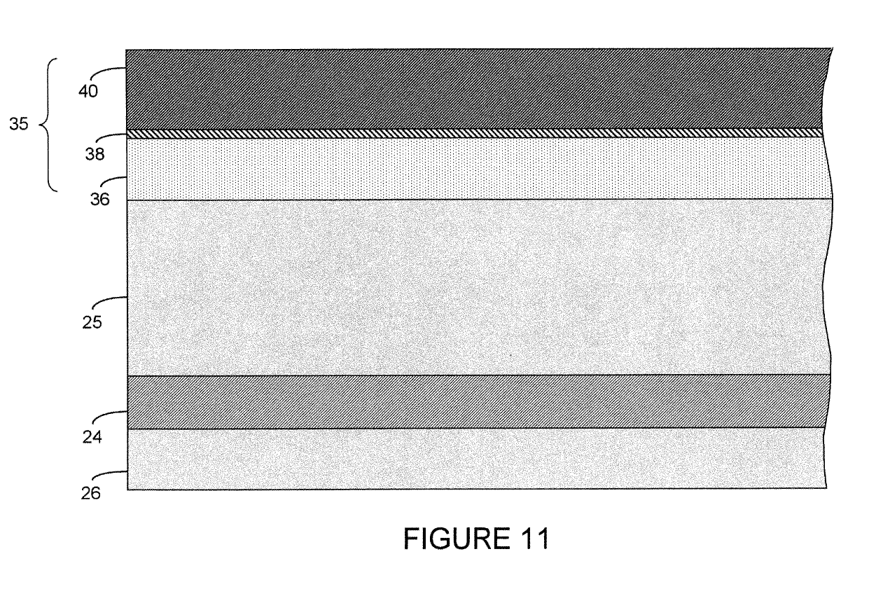

In one exemplary embodiment of the present inventions, the mask includes three or more layers wherein one of the layers is a relatively thin barrier layer (for example, a silicon nitride layer) which prevents, prohibits, minimizes, inhibits and/or retards diffusion, penetration and/or introduction (herein collectively “diffusion” or other forms thereof, i.e., diffusing, diffused, etc.) of nitrogen atoms to the material(s) or layer(s) underlying the mask. With reference to FIG. 11, mask 35 (for example, a hard mask), in one embodiment, includes pad layer 36, disposed on a semiconductor material or layer 25 (for example, polycrystalline, monocrystalline or amorphous silicon, silicon-germanium, gallium arsenide or silicon carbide). The pad layer 36 may be a silicon oxide material which is, for example, thermally grown to a thickness of, for example, 5 to 10 nm. Notably, however, any technique/process, whether now known or later developed, to grow, deposit and/or provide a pad layer is intended to fall within the scope of the present inventions.

The mask 35 further includes barrier layer 38 which is deposited, grown and/or provided on or above (in the event that mask 35 includes additional layers) pad layer 36. In one embodiment, barrier layer 38 is a silicon nitride material having a thickness of less than 3 nm, and preferably less than 2 nm, and more preferably between about 1 to 2 nm. The barrier layer 38 may be deposited and/or provided using an atomic layer deposition technique. Notably, the atomic layer deposition process provides a relatively low deposition rate and generally includes at least two precursors for making an alloy brought to the contact with the surface in turn after each other many times. However, any technique/process whether now known or later developed to grow, deposit and/or provide a relatively thin barrier layer is intended to fall within the scope of the present inventions.

In another embodiment, barrier layer 38 may be a silicon bearing material, for example, an amorphous silicon which is, for example, deposited or formed using an atomic layer deposition process to a thickness of less than 3 nm, preferably less than 2 nm, and more preferably about 1 to about 2 nm. Indeed, in yet another embodiment, barrier layer 38 may be a silicon bearing material, for example, an amorphous silicon, (less than 3 nm, and preferably about 1 to about 2 nm) including a high dose shallow depth plasma nitridation (using, for example, a very shallow nitrogen ion implantation tool such as plasma induced ion implantation tool, decoupled plasma tool and/or slot-plane nitridation tool) of, for example, less than or equal to 30-60 at % of N within (about 1 to about 2 nm) barrier layer 38. The barrier layer 38 may also be a nitrogen bearing material, for example, formed and/or provided using a high dose shallow depth plasma nitridation of pad layer 36 (which is, for example, a silicon oxide) having, for example, less than or equal to 20-40 at % of N within about 1 nm of pad layer 36 from the “upper” or exposed surface side thereof.

With continued reference to FIG. 11, mask 35 of this embodiment further includes a relatively thick hard mask layer 40. The relatively thick hard mask layer 40 may be a silicon nitride material to provide suitable and/or predetermined masking properties of mask 35. In one embodiment, mask layer 40 includes a thickness of 50 to 150 nm and is deposited, grown and/or provided using, for example, a low pressure (“LP”) chemical vapor deposited (“CVD”) process, plasma-enhanced (“PE”) CVD process, atmospheric pressure (“AP”) CVD process, rapid thermal nitride (“RTN”) process. Indeed, any technique/process whether now known or later developed to grow, deposit and/or provide a relatively thick hard mask layer is intended to fall within the scope of the present inventions.

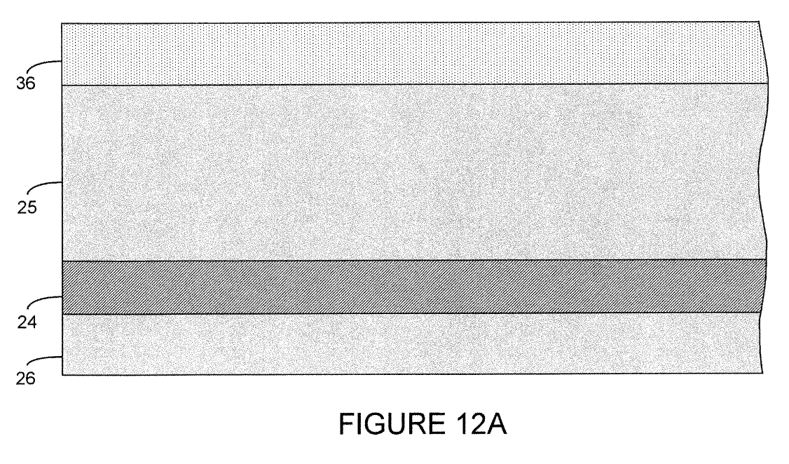

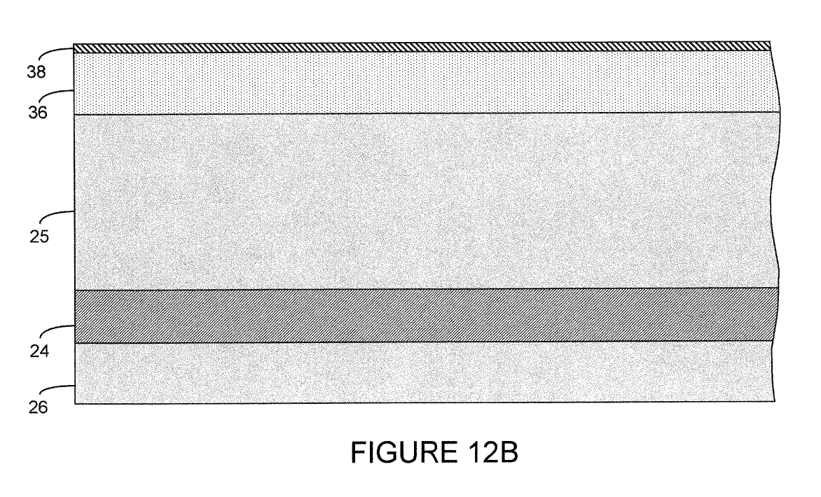

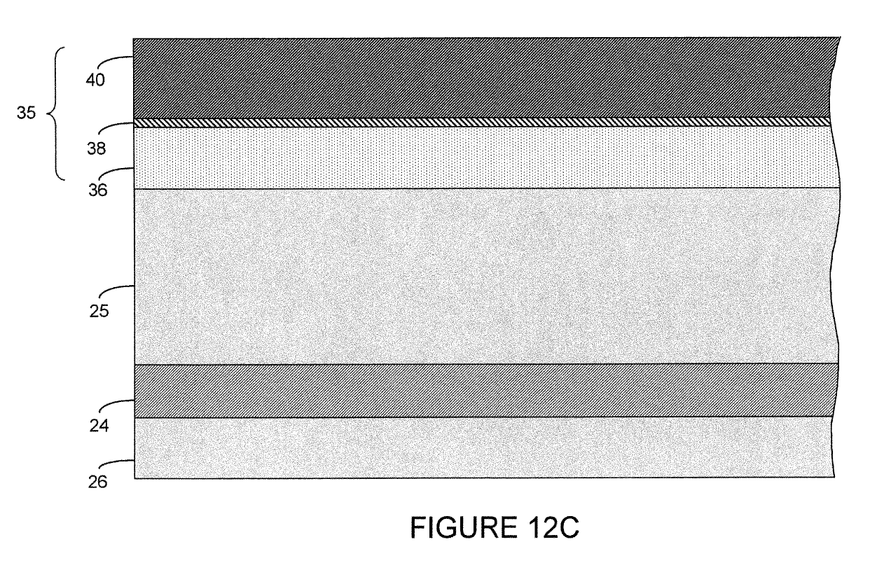

With reference to FIG. 12A, in one exemplary embodiment, a method of manufacturing mask 35 may begin with growing, depositing and/or providing pad layer 36 on semiconductor layer 25. As noted above, pad layer 36 may be a silicon oxide material which is, for example, thermally grown to a thickness of, for example, 5 to 10 nm. Thereafter, barrier layer 38 may be deposited, grown and/or provided on or above (in the event that mask 35 includes additional layers) pad layer 36. (See, FIG. 12B).

As noted above, in one embodiment, barrier layer 38 may be a silicon nitride material which is deposited using an atomic layer deposition process to a thickness of less than 3 nm, preferably less than 2 nm, and more preferably about 1 to about 2 nm. In another embodiment, barrier layer 38 is an amorphous silicon, for example, deposited or formed using an atomic layer deposition process to a thickness of less than 3 nm, and preferably less than 2 nm, and more preferably between about 1 to about 2 nm. Indeed, in yet another embodiment, barrier layer 38 may be an amorphous silicon (about 1 to about 2 nm) including a high dose shallow depth plasma nitridation (using, for example, a very shallow nitrogen ion implantation tool such as plasma induced ion implantation tool, decoupled plasma tool and/or slot-plane nitridation tool) of, for example, less than or equal to 30-60 at % of N within (about 1 to about 2 nm) barrier layer 38. The barrier layer 38 may also be a nitrogen bearing material formed and/or provided using a high dose shallow depth plasma nitridation of pad layer 36 (which is, for example, a silicon oxide) having, for example, less than or equal to 20-40 at % of N within about 1 nm of pad layer 36 from the “upper” or exposed surface side thereof.

With reference to FIG. 12C, hard mask layer 40 may then be deposited, grown and/or provided on or above (in the event that mask 35 includes additional layers) barrier layer 38. The relatively thick hard mask layer 40 may be a silicon nitride material to provide suitable masking properties. In one embodiment, mask layer 40 includes a thickness of 50 to 150 nm. As noted above, during formation of hard mask layer 40, barrier layer 38 prevents, prohibits, minimizes, inhibits and/or retards diffusion of nitrogen atoms, which are introduced during the growth and/or deposition of hard mask layer 40, to the material(s) or layer(s) underlying mask 35. In this illustrative embodiment, barrier layer 38 prevents, prohibits, minimizes, inhibits and/or retards diffusion of nitrogen atoms into or on semiconductor layer 25. As such, barrier layer 38 prevents, prohibits, minimizes, inhibits and/or retards nitridation of the material at or near the surface of semiconductor layer 25 (for example, polycrystalline, monocrystalline or amorphous silicon) at or near the interface of pad layer 36 and semiconductor layer 25.

In another aspect, the present inventions are directed to an electrical isolation region and a method of manufacturing such a region. The electrical isolation region of the present inventions includes a plurality of layers and/or materials (wherein one of the layers or materials is a relatively thin barrier layer of, for example, a silicon nitride or amorphous silicon) which provides suitable and/or predetermined electrical isolation. In addition, in those circumstances where the electrical isolation region includes a relatively thick nitrogen bearing material (for example, silicon nitride), the relatively thin barrier layer may minimize, retard and/or prevent nitridation of the material or layer (for example, a semiconductor material such as polycrystalline, monocrystalline or amorphous silicon, silicon-germanium, gallium arsenide or silicon carbide) adjacent to or in contact with the electrical isolation region. In this regard, the relatively thin barrier layer (for example, a silicon nitride layer) may prevent, prohibit, minimize and/or retard diffusion, penetration and/or introduction (as noted above, herein collectively “diffusion” or other forms thereof, i.e., diffusing, diffused, etc.) of nitrogen atoms to the material(s) or layer(s) adjacent to or in contact with the electrical isolation region.

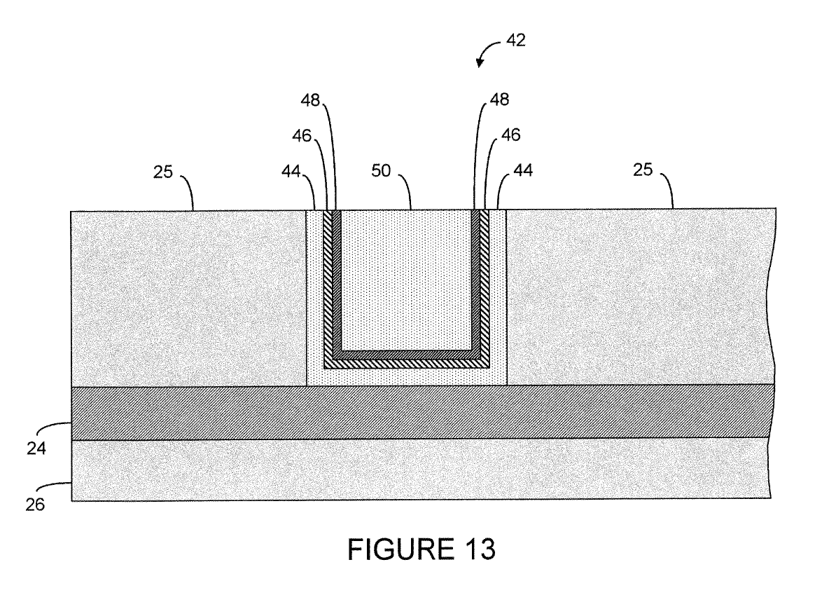

With reference to FIG. 13, trench isolation region 42 (for example, shallow trench isolation (STI)), in one embodiment, includes first liner layer 44, disposed on a semiconductor material or layer 25 (for example, polycrystalline, monocrystalline or amorphous silicon, silicon-germanium, gallium arsenide or silicon carbide). The first liner layer 44 may be a silicon oxide material which is, for example, thermally grown to a thickness of, for example, 3 to 10 nm. Notably, however, any material and/or technique/process, whether now known or later developed, to grow, deposit and/or provide the first liner layer is intended to fall within the scope of the present inventions.

The trench isolation region 42 further includes barrier layer 38 which may be deposited, grown and/or provided on or above first liner layer 44 (in the event that isolation region 42 includes layers in addition to first liner layer 44). In one embodiment, barrier layer 46 is a silicon nitride material, for example, having a thickness of less than 3 nm, and preferably less than 2 nm, and more preferably between about 1 to 2 nm. The barrier layer 46 may be deposited and/or provided using an atomic layer deposition technique. As noted above, the atomic layer deposition process provides a relatively low deposition rate and often includes at least two precursors for making an alloy brought to contact with the surface in turn after each other many times. However, any technique/process whether now known or later developed to grow, deposit and/or provide a relatively thin barrier layer is intended to fall within the scope of the present inventions.

In another embodiment, barrier layer 46 may be a silicon bearing material, for example, an amorphous silicon, having a thickness of, for example, less than 3 nm, and preferably less than 2 nm, and more preferably between about 1 to about 2 nm, which includes a high dose shallow depth plasma nitridation (using, for example, decoupled plasma or slot-plane nitridation tools) of, for example, less than or equal to 30-60 at % of N within barrier layer 46. The barrier layer 46 may also be a nitrogen bearing material formed and/or provided using a high dose shallow depth plasma nitridation of first liner layer 44 (which is, for example, a silicon oxide) having, for example, less than or equal to 20-40 at % of N within about 1 nm of first liner layer 44 from the “upper” or exposed surface side thereof.

With continued reference to FIG. 13, trench isolation region 42 of this embodiment may further include a second liner layer 48 disposed on barrier layer 38. The second liner layer 48 may be a silicon nitride material which is, for example, grown, deposited and/or provided using a CVD process, to a thickness of, for example, 3 to 10 nm. Notably, however, any material and/or technique/process, whether now known or later developed, to grow, deposit and/or provide the second liner layer is intended to fall within the scope of the present inventions.

The trench isolation region 42 of this embodiment may further include a relatively thick electrical isolation material 50. The electrical isolation material 50 may be an electrically insulating material, for example, silicate glass materials such as phosphosilicate (“PSG”), a silicon oxide (for example, a high density plasma created silicon oxide), a silicon nitride, tetraethoxysilane (TEOS) or the like. In one embodiment, electrical isolation material 50 includes a thickness sufficient to fill the trench. Any technique/process and materials, whether now known or later developed to grow, deposit and/or provide a relatively thick electrical isolation material is intended to fall within the scope of the present inventions.

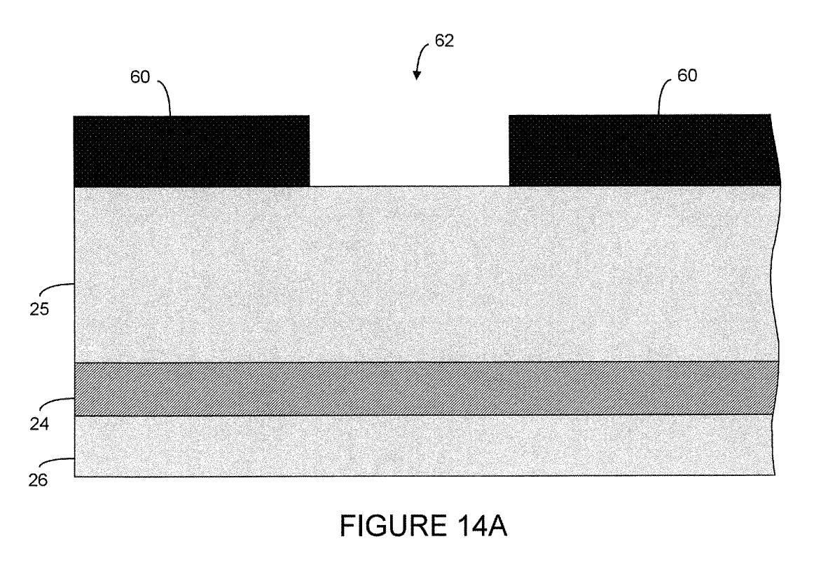

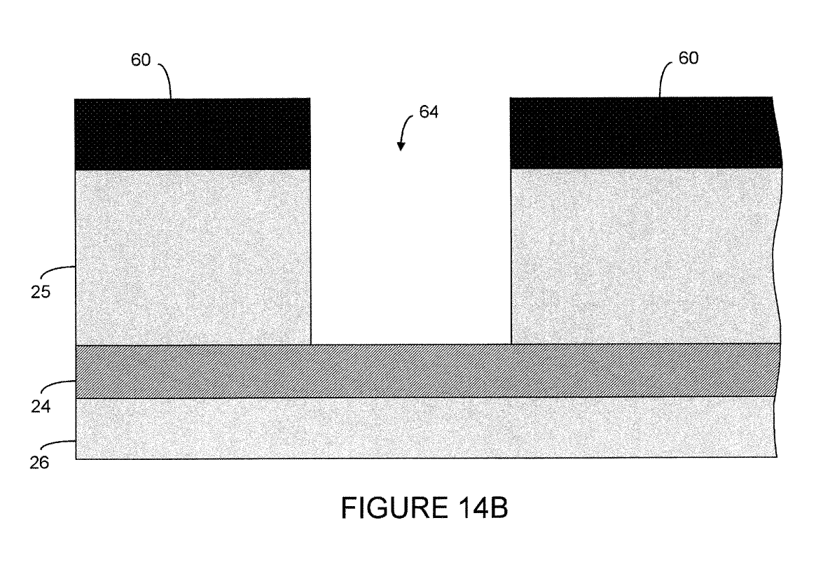

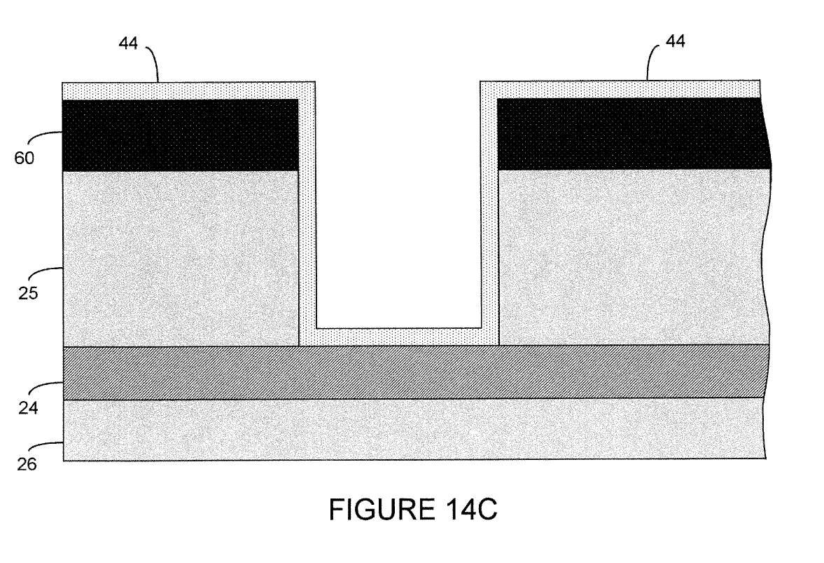

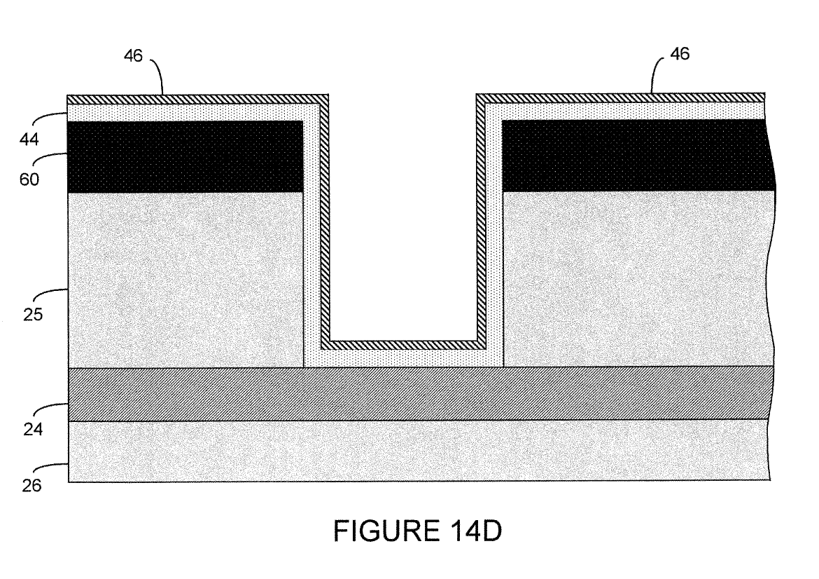

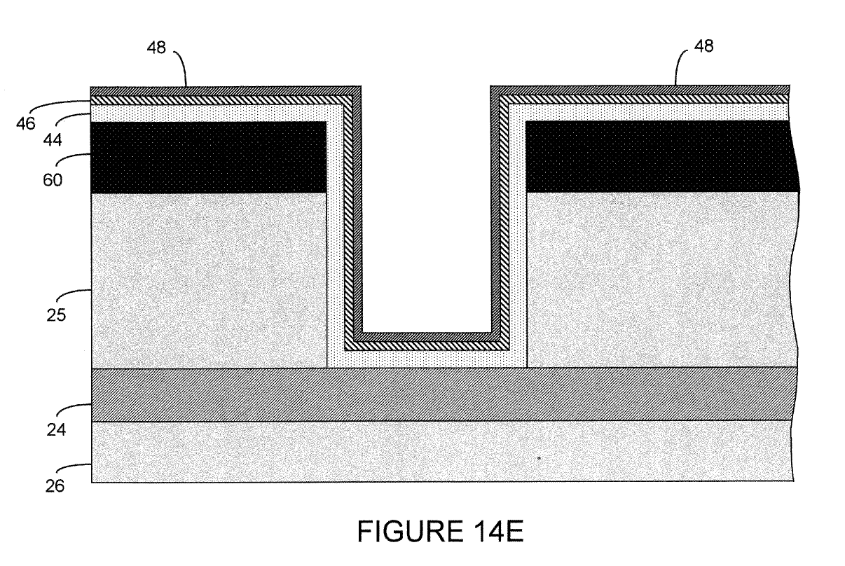

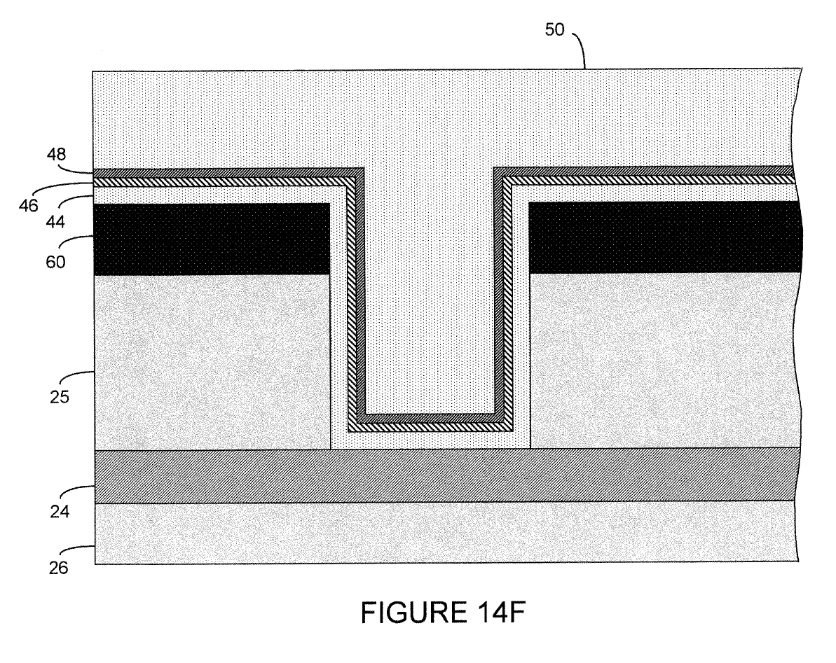

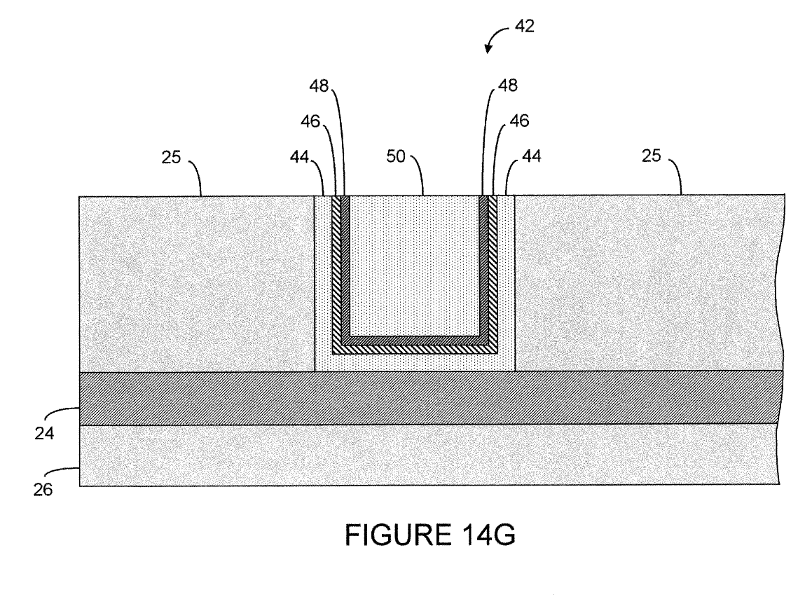

With reference to FIG. 14A, in one exemplary embodiment, a method of manufacturing trench isolation region (for example, shallow trench isolation (STI)) may begin with providing a properly defined mask 60 having a window 62. The semiconductor layer 25 may be etched, for example, via conventional anisotropic techniques, to form and/or provide a shallow isolation trench 64 in which trench isolation region will reside. (See, FIG. 14B). Thereafter, first liner layer 44 may be grown, deposited and/or provided. (See, FIG. 14C). As noted above, first liner layer 44 may be a silicon oxide material which is, for example, thermally grown to a thickness of, for example, 3 to 10 nm.

With reference to FIG. 14D, barrier layer 46 may be deposited, grown and/or provided on or above first liner layer 44 (in the event that trench isolation region includes additional layers). In one embodiment, barrier layer 46 is a silicon nitride material which is deposited using an atomic layer deposition process to a thickness of less than 3 nm, and preferably less than 2 nm, and more preferably between about 1 to about 2 nm. As noted above, in another embodiment, barrier layer 46 may be an amorphous silicon, having a thickness of less than 3 nm, and preferably less than 2 nm, and more preferably between about 1 to about 2 nm, and including a high dose shallow depth plasma nitridation (using, for example, decoupled plasma or slot-plane nitridation tools) of, for example, less than or equal to 30-60 at % of N within barrier layer 46. Indeed, in yet another embodiment, barrier layer 46 may be a nitrogen bearing material formed and/or provided using a high dose shallow depth plasma nitridation of first liner layer 44 (which is, for example, a silicon oxide) having, for example, less than or equal to 20-40 at % of N within about 1 nm of first liner layer 44 from the “upper” or exposed surface side thereof.

Thereafter, second liner layer 48 may be grown, deposited and/or provided. (See, FIG. 14E). In this exemplary embodiment, second liner layer 44 may be a silicon nitride material which is, for example, deposited to a thickness of, for example, 3 to 10 nm. During formation of second liner layer 48, barrier layer 46 prevents, prohibits, minimizes, inhibits and/or retards diffusion of nitrogen atoms, which are introduced during the growth and/or deposition of second liner layer 48, into or on the material(s) or layer(s) first liner layer 44 (which, in the illustrative embodiment is semiconductor layer 25). As such, barrier layer 46 prevents, prohibits, minimizes, inhibits and/or retards nitridation of the material at or near the surface of semiconductor layer 25 (for example, polycrystalline, monocrystalline or amorphous silicon) at or near the interface of first liner layer 44 and semiconductor layer 25.

With reference to FIG. 14F, electrical isolation material 50 may then be deposited, grown and/or provided on second liner layer 48. As noted above, electrical isolation material 50 may be, for example, a PSG, a silicon oxide (for example, a high density plasma created silicon oxide), a silicon nitride, a TEOS or the like. In the illustrative embodiment, electrical isolation material 50 includes a thickness which is sufficient to fill trench 62 (compare FIGS. 14B and 14F). Any technique/process and materials, whether now known or later developed to grow, deposit and/or provide a relatively thick electrical isolation material is intended to fall within the scope of the present inventions.

Notably, where electrical isolation material 50 includes a silicon nitride material, during formation thereof, barrier layer 46 prevents, prohibits, minimizes, inhibits and/or retards diffusion of nitrogen atoms, which are introduced during the growth and/or deposition of electrical isolation material 50, to the material(s) or layer(s) semiconductor layer 25. In this way, barrier layer 46 prevents, prohibits, minimizes, inhibits and/or retards nitridation of the material at or near the surface of semiconductor layer 25 (for example, polycrystalline, monocrystalline or amorphous silicon) at or near the interface of first liner layer 44 and semiconductor layer 25.

With reference to FIG. 14G, the manufacturing may continue with a planarization process, for example, chemical mechanical polishing (“CMP”), to remove the materials/layers (for example, first liner layer 44, barrier layer 46, second liner layer 48 and electrical isolation material 50) on mask 60. In addition, mask 60 may be removed to facilitate additional/subsequent processing (for example, providing a gate dielectric layer and gate layers).

Notably, prior to performing the planarization process, an annealing step may be performed. In this way, any voids and/or impurities in the layers may be addressed and/or removed.

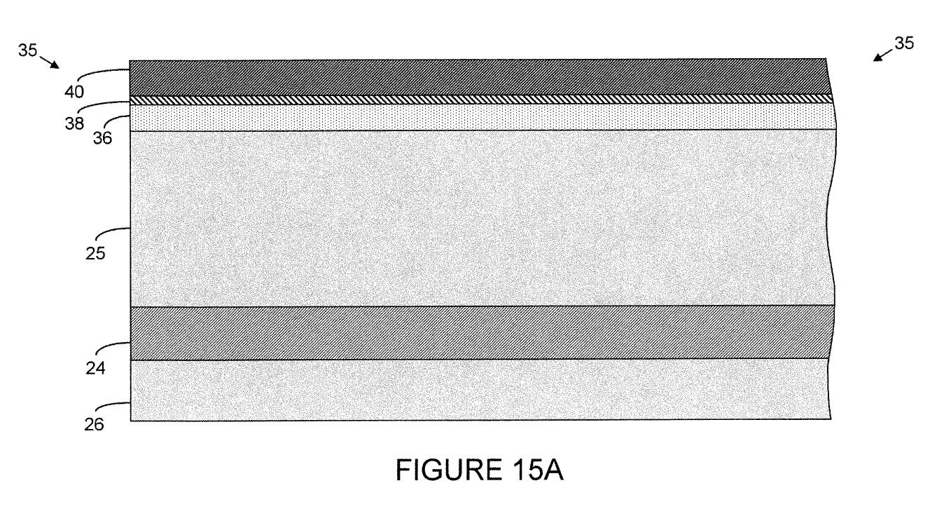

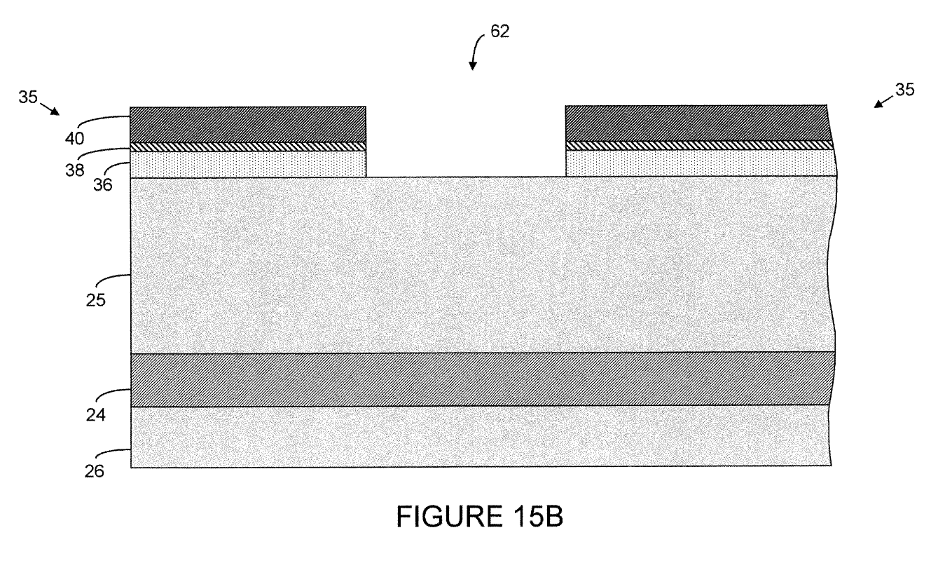

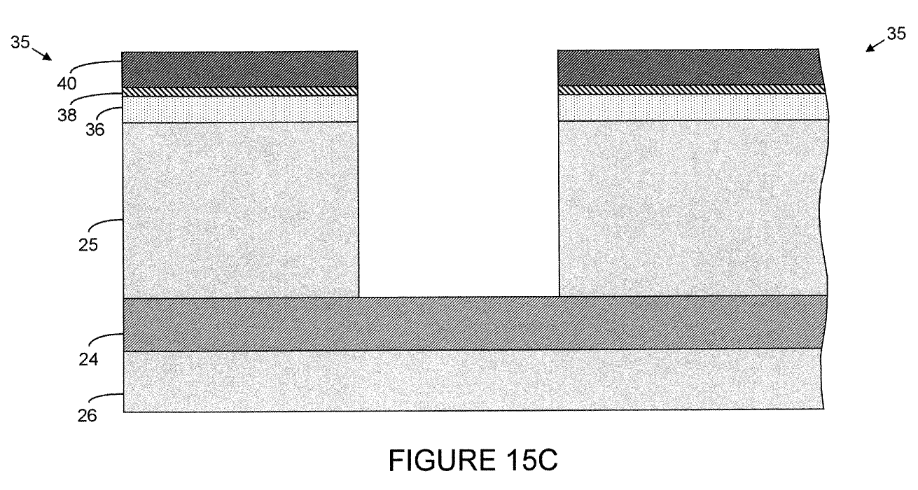

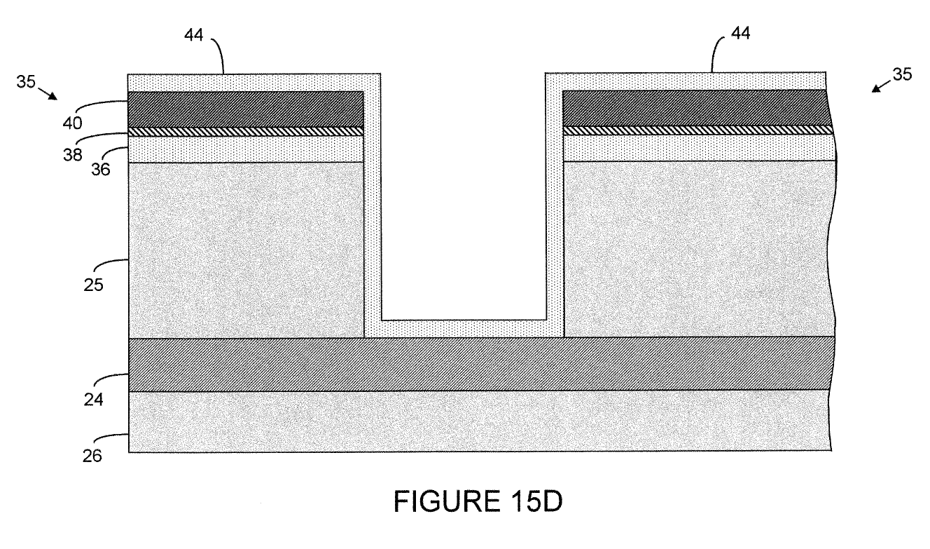

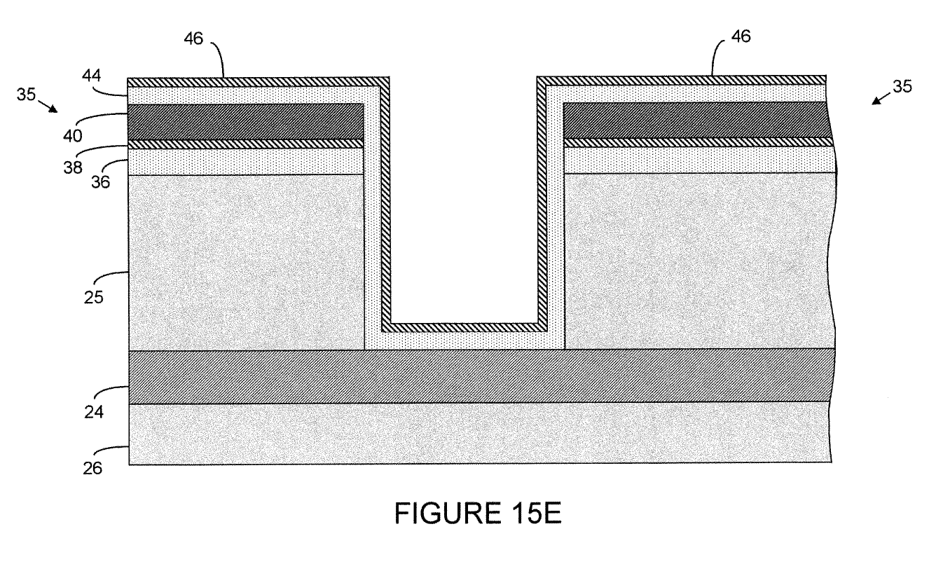

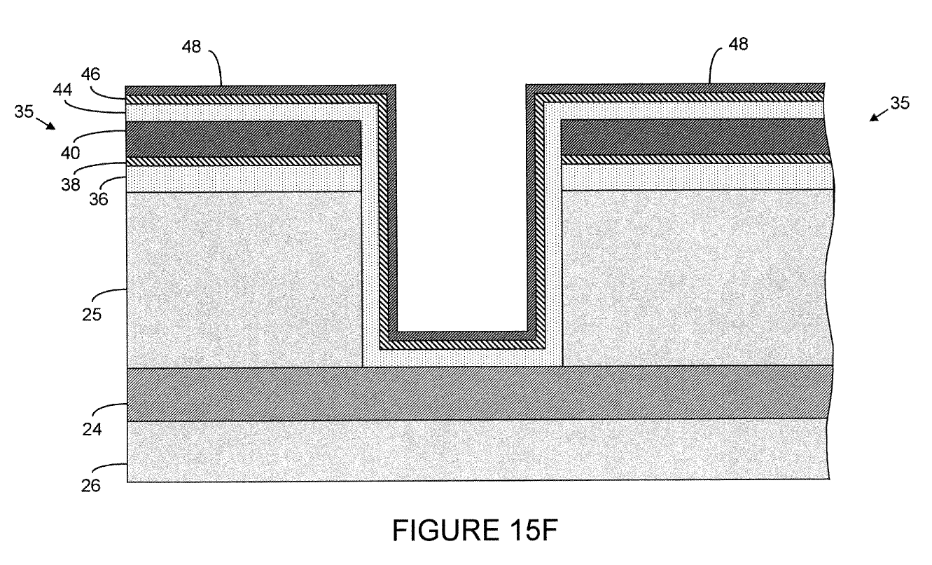

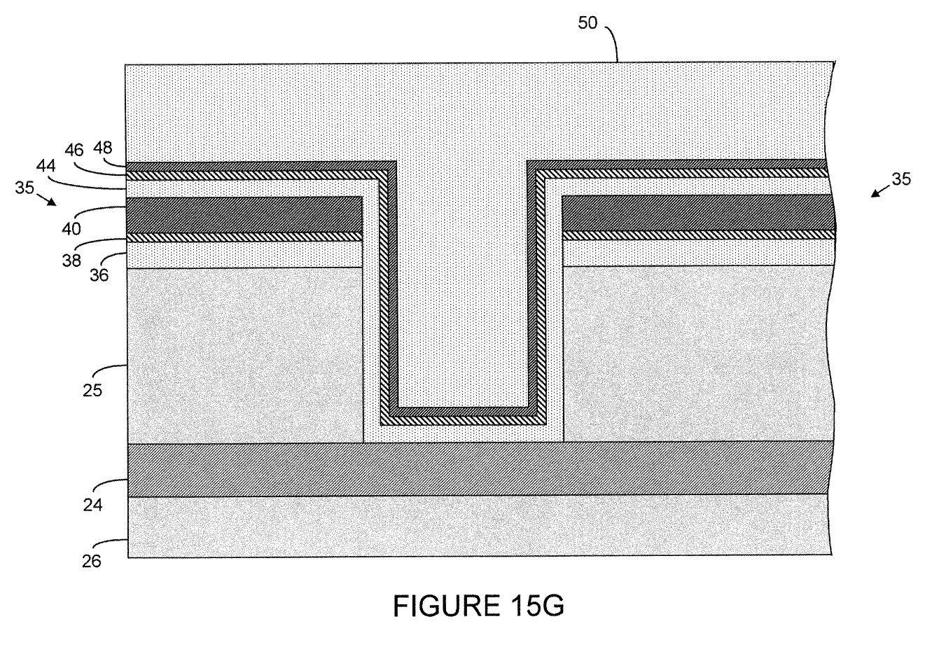

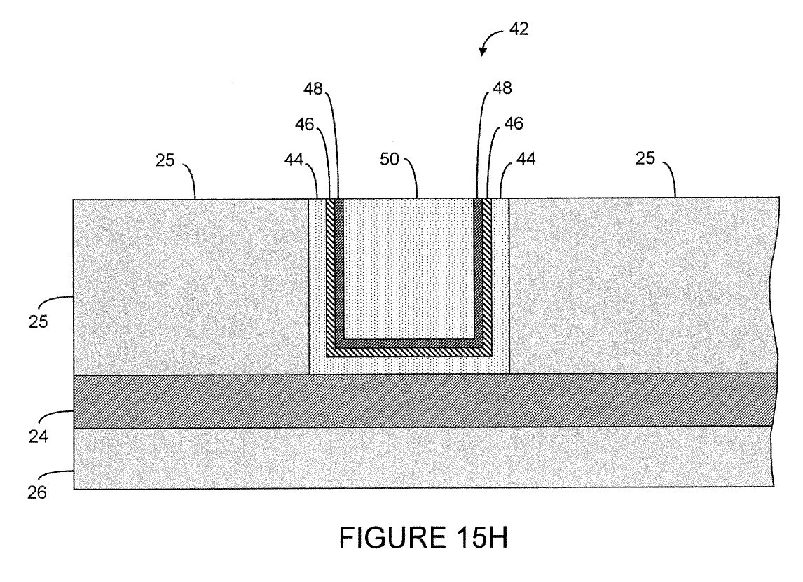

In another aspect of the present inventions, the inventive mask described and/or illustrated herein (see, for example, FIGS. 11 and 12, and the text associated therewith) may be employed in conjunction with the manufacture of the trench isolation region (for example, shallow trench isolation (STI)) described immediately above. In this regard, with reference to FIG. 15A, mask 35—as described above—may be formed and/or provided on semiconductor layer 25. Thereafter, a window 62 may be formed, using conventional processes. (See, FIG. 15B). The semiconductor layer 25 may then be etched, for example, via conventional anisotropic techniques, to form and/or provide trench 64 in which the trench isolation region will reside. (See, FIG. 15C). With reference to FIGS. 15D-15H, trench isolation region 42 may be manufactured using the same or similar processing as described and illustrated above with respect to FIGS. 14C-14G. For the sake of brevity, the discussion regarding these processes will not be repeated.

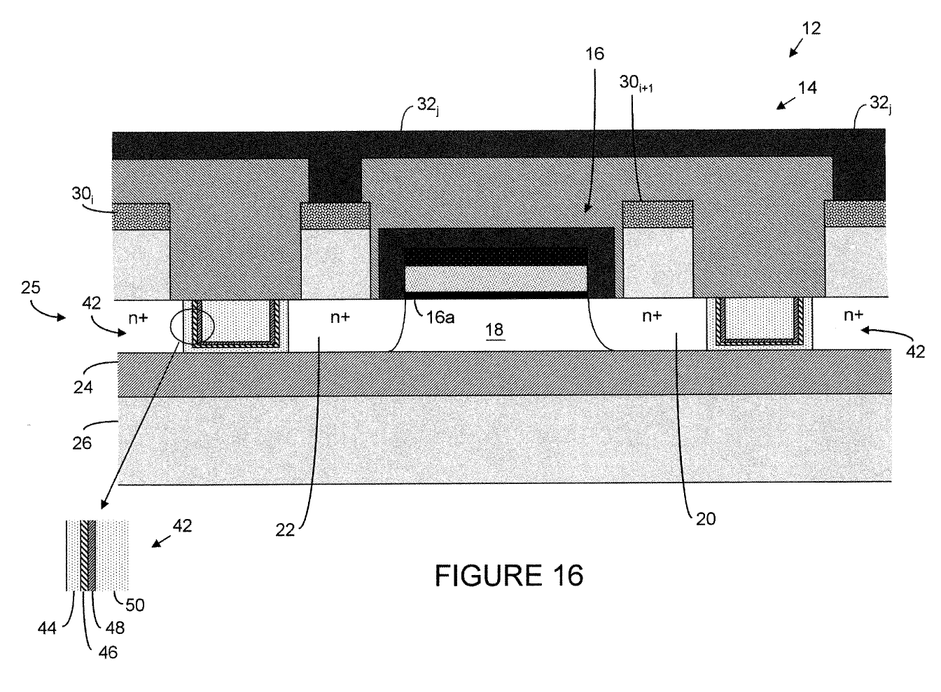

The trench isolation regions 42 may be formed, provided and disposed between adjacent transistors of an integrated circuit device prior to deposition, growth and/or formation of gate dielectric layer and other processing employed to form such transistors. (See, for example, FIG. 16). Notably, in the illustrative embodiment of FIG. 16, isolation regions 42 (for example, shallow trench isolation regions) are formed and/or provided between adjacent transistors. In other embodiments, adjacent transistors (for example, of adjacent memory cells in adjacent rows of memory cells) share source and/or drain regions and, as such, may or may not include isolation regions 42 between both the source and drain regions. All configurations and/or architectures of the memory cell array layout (for example, (i) separated source and/or drain regions of transistors of adjacent memory cells and/or (ii) shared source and/or drain regions of transistors of adjacent memory cells) are intended to fall within the scope of the present inventions.

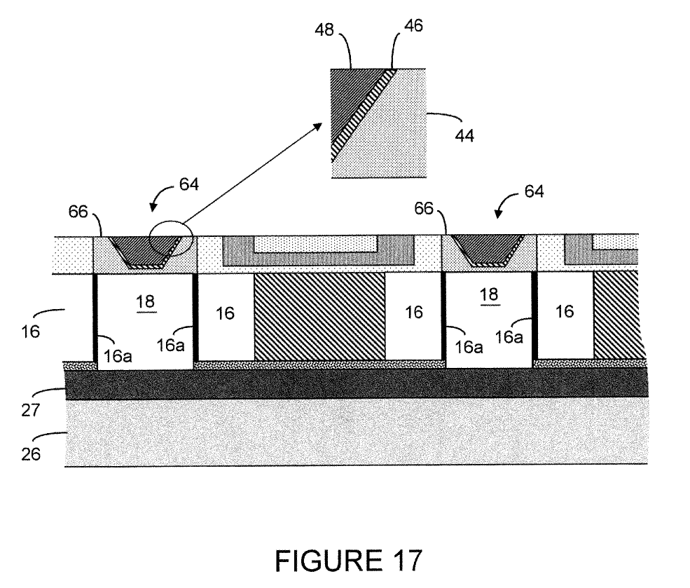

Notably, although many of the embodiments of the present inventions have been described in the context of the trench type isolation regions (for example, shallow trench isolation), the present inventions may be implemented in conjunction with any isolation region type or architecture. For example, an isolation region implementing one or more aspects of the present inventions may be formed and/or provided in a region or layer which is on or above the substrate—such as, on or above the gate of a pillar or FinFET transistor. For example, with reference to FIG. 17, the present inventions may be employed to prohibit, minimize, reduce, inhibit and/or retard diffusion, penetration and/or introduction of nitrogen atoms and/or nitrogen radicals of certain materials of isolation regions 64 into body region 18 of a transistor having a pillar architecture (which may be disposed on a highly doped semiconductor region 27 which may be disposed on substrate 26). In this regard, prior to deposition of the material of layer 48, barrier layer 46 is deposited, provided, formed and/or grown using any of the techniques and/or materials described and/or illustrated herein; for the sake of brevity, such discussions will not be repeated. The barrier layer 46 may be deposited, provided, formed and/or grown on, over or above a region of the transistor (for example, body region 18) to prohibit, minimize, reduce, inhibit and/or retard nitrogen atoms and/or nitrogen radicals of a subsequent deposition of a nitrogen bearing material (of, for example, layer 48 which may be a silicon nitride material, such as, for example, Si₃N₄, deposited via a CVD process) from diffusing, penetrating and/or introducing into the underlying region(s) during such subsequent deposition.

With continued reference to FIG. 17, in this illustrative embodiment, barrier layer 46 may be deposited, provided, formed and/or grown on a material of layer 66 which may be a silicon oxide material. In one embodiment, the material of layer 66 may be deposited, provided, formed and/or grown via a CVD process and thereafter thermally re-oxidized. The barrier layer 48 prohibits, minimizes, reduces, inhibits and/or retards nitrogen atoms and/or nitrogen radicals of layer 48 of isolation regions 64 from diffusing into body region 18 during deposition of layer 48 As indicated above, barrier layer 46 of the illustrative embodiment of FIG. 17 may be deposited, provided, formed and/or grown using any of the techniques and/or materials described and/or illustrated herein; for the sake of brevity, such discussions will not be repeated.

Thus, in manufacturing an isolation region, the deposition of an insulating layer comprising a nitrogen bearing material may be separated into a first deposition of a barrier layer, as described above, and a second deposition of a second layer wherein the barrier prohibits, minimizes, inhibits and/or retards nitrogen or nitrogen radicals from diffusing or penetrating an underlying region or material (for example, the channel or body of a transistor (for example, an electrically floating body transistor) or the interfacial region between the source/drain regions and associated channel or body region of a transistor (for example, an electrically floating body transistor). Reduction in the nitridation may result in a significant performance and retention time improvement.

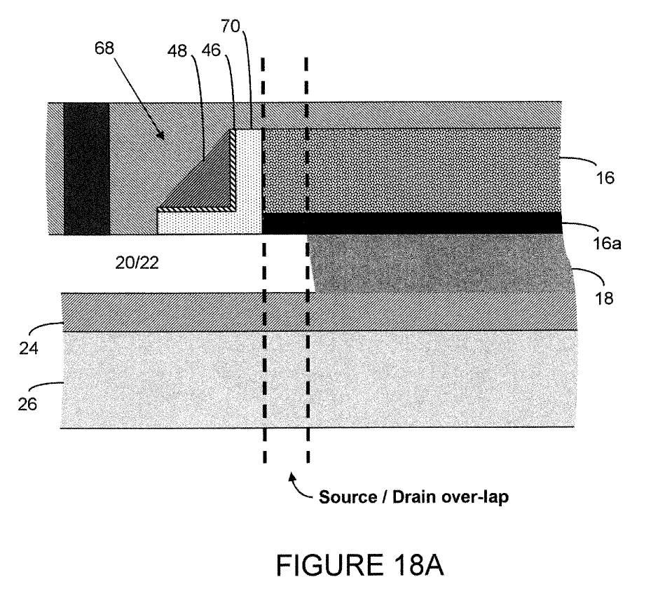

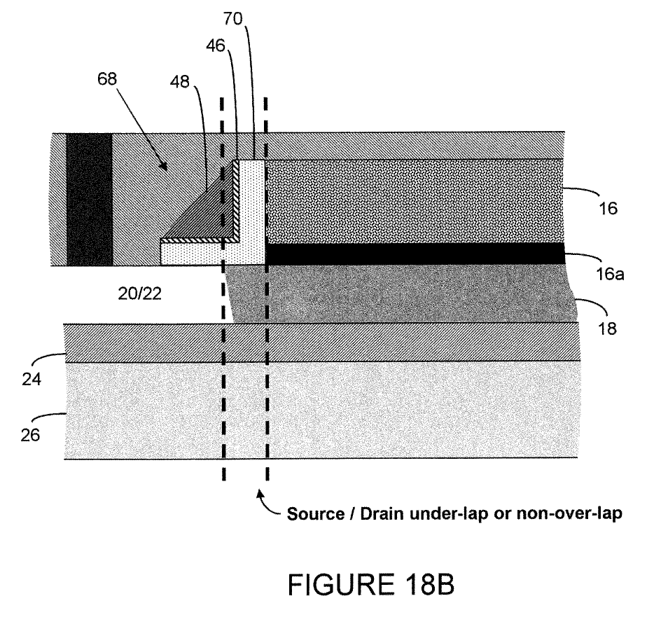

Moreover, the present inventions may be implemented in conjunction with other aspects, elements and/or components of integrated circuits and integrated circuit manufacturing. For example, the present inventions may be employed in fabricating spacer structure. With reference to FIGS. 18A and 18B, in one embodiment, spacer 68 may include and be fabricated using one or more of the inventions described and/or illustrated herein. For example, spacer 68 includes barrier layer 46 which prohibits, minimizes, reduces, inhibits and/or retards diffusion, penetration and/or introduction of nitrogen atoms and/or nitrogen radicals of the material of layer 48 into body region 18 and/or source/drain regions 20 and 22 of a transistor. In this regard, prior to deposition of the material of layer 48, barrier layer 46 is deposited, provided, formed and/or grown using any of the techniques and/or materials described and/or illustrated herein; for the sake of brevity, such discussions will not be repeated.

With continued reference to FIGS. 18A and 18B, in this illustrative embodiment, barrier layer 46 may be deposited, provided, formed and/or grown on material of layer 70 which may be, for example, a silicon oxide material. The barrier layer 48 prohibits, minimizes, reduces, inhibits and/or retards nitrogen atoms and/or nitrogen radicals of layer 48 of the material of layer 70 from diffusing into body region 18 during deposition of layer 48. In one embodiment, barrier layer 46 is a silicon nitride material which is deposited using an atomic layer deposition process to a thickness of less than 3 nm, and preferably less than 2 nm, and more preferably between about 1 to about 2 nm. As noted above, in another embodiment, barrier layer 46 may be an amorphous silicon, having a thickness of less than 3 nm, and preferably less than 2 nm, and more preferably between about 1 to about 2 nm, and including a high dose shallow depth plasma nitridation (using, for example, decoupled plasma or slot-plane nitridation tools) of, for example, less than or equal to 30-60 at % of N within barrier layer 46. Indeed, in yet another embodiment, barrier layer 46 may be a nitrogen bearing material formed and/or provided using a high dose shallow depth plasma nitridation of first liner layer 44 (which is, for example, a silicon oxide) having, for example, less than or equal to 20-40 at % of N within about 1 nm of first liner layer 44 from the “upper” or exposed surface side thereof

Again, barrier layer 46 of the illustrative embodiment of FIGS. 18A and 18B may be deposited, provided, formed and/or grown using any of the techniques and/or materials described and/or illustrated herein; for the sake of brevity, such discussions will not be repeated. Thus, in manufacturing a spacer, the deposition of a layer comprising a nitrogen bearing material may be separated into a first deposition of a barrier layer, as described above, and a second deposition of a second layer wherein the barrier prohibits, minimizes, inhibits and/or retards nitrogen or nitrogen radicals from diffusing or penetrating an underlying region or material (for example, the channel or body of a transistor (for example, an electrically floating body transistor) or the interfacial region between the source/drain regions and associated channel or body region of a transistor (for example, an electrically floating body transistor). Reduction in the nitridation of such areas or regions may result in a significant performance and retention time improvement.

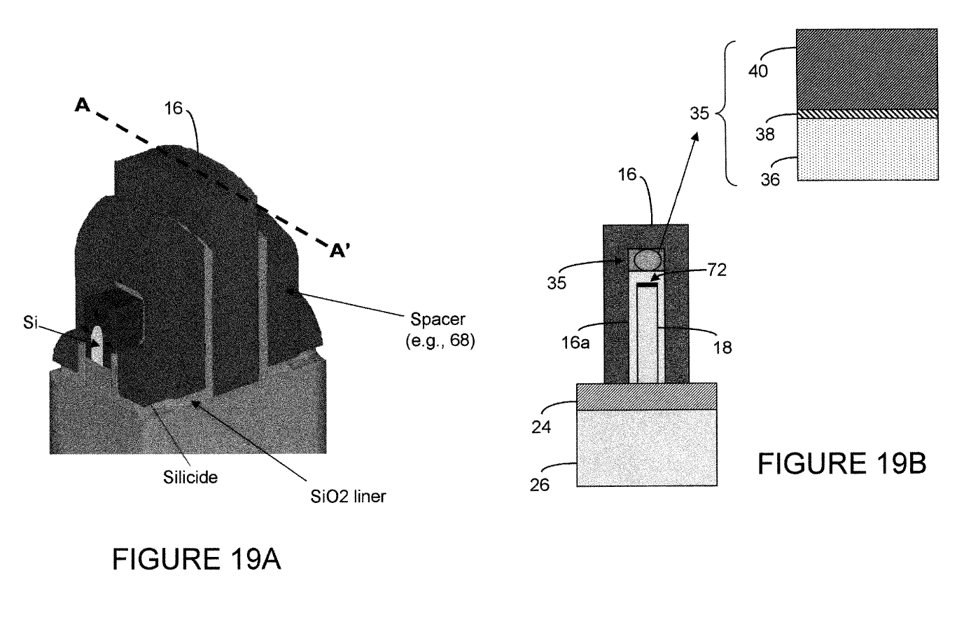

Moreover, as intimated above, the inventive masks and masking techniques are applicable to many aspects, elements and/or components of integrated circuits and the manufacturing thereof. For example, the inventive mask may be employed to fabricate a portion of a FinFET type-transistor. With reference to FIGS. 19A and 19B, a mask according to one or more of the inventive embodiments may be employed to prohibit, minimize, reduce, inhibit and/or retard nitrogen atoms and/or nitrogen radicals of a nitrogen bearing material of the mask into a portion of the body or channel (here, a distal portion of the “fin”—see, drawing indicator 72). The barrier layer of the mask 35 may be deposited, provided, formed and/or grown using any of the techniques and/or materials described and/or illustrated herein; for the sake of brevity, such discussions will not be repeated.

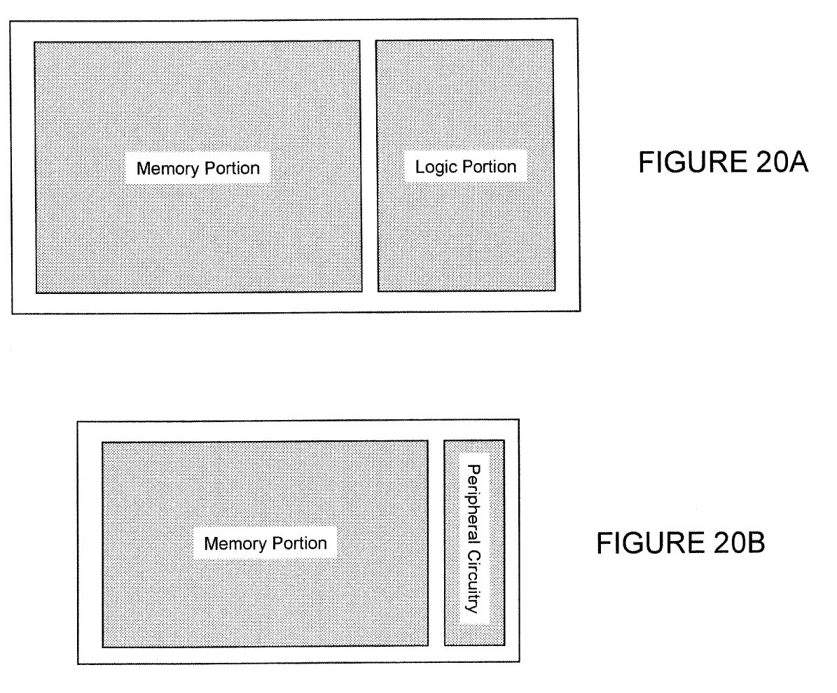

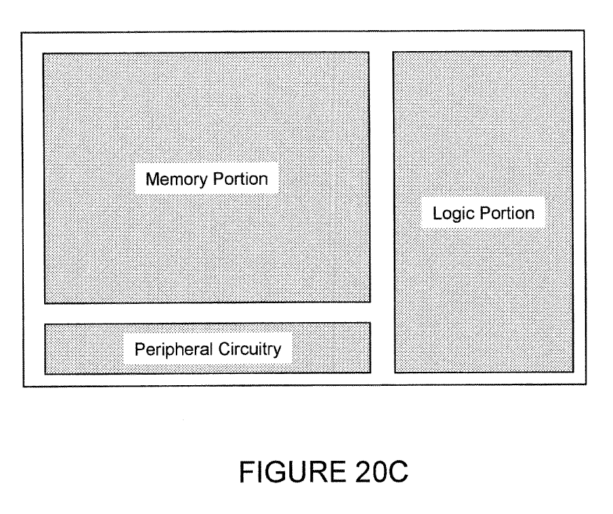

As noted above, the present inventions may be implemented in an integrated circuit device includes memory section (having a plurality of memory cells, for example, PD or FD SOI memory transistors) whether or not the integrated circuit includes a logic section (having, for example, high performance transistors, such as FinFET, multiple gate transistors, and/or non-high performance transistors (for example, single gate transistors that do not possess the performance characteristics of high performance transistors—not illustrated)). In this regard, the present inventions may be implemented in an integrated circuit device having a memory portion and a logic portion (see, for example, FIGS. 20A and 20C), or an integrated circuit device that is primarily a memory device (see, for example, FIG. 20B). The memory cell arrays may be comprised of n-channel, p-channel and/or both types of transistors. Indeed, circuitry that is peripheral to the memory array (for example, data sense circuitry (for example, sense amplifiers or comparators), memory cell selection and control circuitry (for example, word line and/or source line drivers), and/or the row and column address decoders) may include p-channel and/or n-channel type transistors.

Further, as mentioned above, the present inventions may be employed in conjunction with any memory cell technology now known or later developed. For example, the present inventions may be implemented in conjunction with a memory array, having a plurality of memory cells each including an electrically floating body transistor. (See, for example, (1) U.S. Pat. No. 6,969,662, (2) Okhonin et al., U.S. Patent Application Publication No. 2006/0131650 (“Bipolar Reading Technique for a Memory Cell Having an Electrically Floating Body Transistor”), (3) Okhonin et al., U.S. Patent Application Publication No. 2007/0058427 (“Memory Cell and Memory Cell Array Having an Electrically Floating Body Transistor, and Methods of Operating Same”), (4) Okhonin, U.S. Patent Application Publication No. 2007/0138530 (“Electrically Floating Body Memory Cell and Array, and Method of Operating or Controlling Same”), (5) Okhonin et al., U.S. Patent Application Publication No. 2007/0187775 (“Multi-Bit Memory Cell Having Electrically Floating Body Transistor, and Method of Programming and Reading Same”), and (6) Okhonin, U.S. Patent Application Publication No. 2008/0180995, (“Semiconductor Device with Electrically Floating Body”). In this regard, the memory cell may consist of a PD or a FD SOI transistor (or transistor formed on or in bulk material/substrate) having a gate, which is disposed adjacent to the electrically floating body and separated therefrom by a gate dielectric. The transistors may include a single gate or multiple gate architectures made with the planar or any 3D technology now known or later developed. The body region of the transistor is electrically floating in view of the insulation or non-conductive region (for example, in bulk-type material/substrate) disposed beneath the body region. The state of memory cell is determined by the concentration of charge within the body region of the SOI transistor.

The memory cells of the memory cell array may be comprised of n-channel, p-channel and/or both types of transistors. Indeed, circuitry that is peripheral to the memory array (for example, sense amplifiers or comparators, row and column address decoders, as well as line drivers (not illustrated in detail herein)) may include p-channel and/or n-channel type transistors. Moreover, the present inventions may be implemented in conjunction with any memory cell array configuration and/or arrangement of the memory cell array. For example, the present inventions may be implemented in a shared source region and/or shared drain region configuration wherein adjacent memory cells source region and/or shared drain region.

There are many inventions described and illustrated herein. While certain embodiments, features, attributes and advantages of the inventions have been described and illustrated, it should be understood that many others, as well as different and/or similar embodiments, features, attributes and advantages of the present inventions, are apparent from the description and illustrations. As such, the embodiments, features, attributes and advantages of the inventions described and illustrated herein are not exhaustive and it should be understood that such other, similar, as well as different, embodiments, features, attributes and advantages of the present inventions are within the scope of the present inventions.

Moreover, the present inventions may be implemented in conjunction with any memory cell array configuration and/or arrangement of the memory cell array. For example, the present inventions may be implemented in a shared source region and/or shared drain region configuration wherein adjacent memory cells source region and/or shared drain region. Indeed, the present inventions may be implemented in conjunction with the inventions and/or embodiments described and illustrated in U.S. Provisional Application Ser. No. 61/065,025, “Integrated Circuit Having Memory Cells Including Gate Material Having High Work Function, and Method of Manufacturing Same”, filed Feb. 8, 2008 (Inventor: Viktor Koldiaev). (See, for example, the gate structure of the transistor illustrated in FIG. 16). For the sake of brevity, the discussion will not be repeated but is incorporated by reference herein in their entirety.

Notably, where the memory cell array is arranged or configured to include a memory cell array having a plurality of memory cells, arranged in a matrix of rows and columns, wherein each memory cell of a given row of memory cells shares a source region and/or a drain region with an adjacent memory cell of an adjacent row of memory cells, the present inventions may be employed in conjunction with the barriers described and illustrated in U.S. patent application Ser. No. 12/268,671 and U.S. Provisional Application Ser. No. 61/004,672 (Inventor: Fazan; hereinafter the “Barrier Application”); the contents of these applications are incorporated by reference herein in their entirety. For the sake of brevity, the discussion will not be repeated, but is incorporated by reference herein in their entirety.

In addition, in those instances where the memory cell array is arranged or configured to include a memory cell array having a plurality of memory cells, arranged in a matrix of rows and columns, wherein each memory cell of a given row of memory cells shares a source region and/or a drain region with an adjacent memory cell of an adjacent row of memory cells, the present inventions may be employed in conjunction with the source/drain processing described and illustrated in U.S. patent application Ser. No. 12/332,413 and U.S. Provisional Application Ser. No. 61/007,103 (Inventor: Liu); the contents of these applications are incorporated by reference herein in their entirety.

Importantly, the present inventions are neither limited to any single aspect nor embodiment thereof, nor to any combinations and/or permutations of such aspects and/or embodiments. Moreover, each of the aspects of the present inventions, and/or embodiments thereof, may be employed alone or in combination with one or more of the other aspects of the present inventions and/or embodiments thereof. For the sake of brevity, many of those permutations and combinations are not discussed separately herein.

As such, the above embodiments of the present inventions are merely exemplary embodiments. They are not intended to be exhaustive or to limit the inventions to the precise forms, techniques, materials and/or configurations disclosed. Many modifications and variations are possible in light of the above teaching. It is to be understood that other embodiments may be utilized and operational changes may be made without departing from the scope of the present inventions. As such, the foregoing description of the exemplary embodiments of the inventions has been presented for the purposes of illustration and description. Many modifications and variations are possible in light of the above teaching. It is intended that the scope of the inventions not be limited solely to the description above.

Further, although exemplary embodiments and/or processes have been described above according to a particular order, the order should not, for the most part, be interpreted as limiting but is merely exemplary. Moreover, implementing and/or including certain processes and/or materials may be added or eliminated. For example, one or more additional liner layers may be incorporated into the trench isolation region before providing the barrier layer. Indeed, a plurality of barrier layers may be employed which either alone or in combination prevent, prohibit, minimize and/or retard diffusion of nitrogen atoms or other contaminants into or on semiconductor layer 25. Such combinations and/or permutations are intended to call within the scope of the present inventions.

The term “depositing” and other forms thereof (i.e., deposit, deposition and/or deposited) in the claims, means, among other things, depositing, creating, forming and/or growing a material (for example, a layer of material). Further, in the claims, the term “etching” and other forms thereof (i.e., etch and/or etched) in the claims, means, among other things, etching, removing and/or patterning a material (for example, all or a portion of a layer of material). In addition, the term “forming” and other forms thereof (i.e., form, formation and/or formed) in the claims means, among other things, fabricating, providing, etching, creating, depositing, implanting, manufacturing and/or growing a region (for example, in a material or a layer of a material). The term “inhibit” and other forms thereof (for example, “inhibiting”) in the claims means prohibit, minimize, inhibit, reduce and/or retard. The term “diffusion” and other forms thereof (for example, “diffusing” or “diffused”) in the claims means diffusion, penetration and/or introduction.

What is claimed is:

1. A method of manufacture of an integrated circuit device including a plurality of memory cells, wherein each memory cell thereof includes at least one transistor, wherein transistors of neighboring memory cells are separated by isolation regions, the method comprising:
depositing a first liner layer in a plurality of isolation trenches;
depositing a barrier layer on or over the first liner layer and in the isolation trenches, wherein the barrier layer includes a thickness of less than 3 nanometers;
depositing a second liner layer on or over the barrier layer and in the isolation trenches, wherein the second liner layer includes a nitrogen bearing material and wherein during deposition of the second liner layer, the barrier layer inhibits diffusion of nitrogen atoms there through; and
depositing an electrical isolation material on or over the second liner layer and in the isolation trenches, wherein isolation regions are disposed between neighboring memory cells and comprise materials of the first liner layer, barrier layer, second liner layer and electrical isolation material.

2. The method of manufacture of claim 1 wherein the barrier layer is a nitrogen bearing material.

3. The method of manufacture of claim 1 wherein depositing the barrier layer further includes depositing the material of the barrier layer to a thickness of about 1 nanometer to about 2 nanometers.

4. The method of manufacture of claim 1 wherein:
the barrier layer is a nitrogen bearing material; and
depositing the barrier layer further includes depositing the material of the barrier layer to a thickness of about 1 nanometer to about 2 nanometers.

5. The method of manufacture of claim 4 wherein depositing the barrier layer includes depositing the barrier layer using atomic layer deposition.

6. The method of manufacture of claim 1 wherein the barrier layer is a silicon bearing material.

7. The method of manufacture of claim 6 wherein the barrier layer is an amorphous silicon material.

8. The method of manufacture of claim 7 wherein depositing the barrier layer includes using nitrogen ion implantation.

9. The method of manufacture of claim 1 wherein:
depositing the first liner layer in the plurality of isolation trenches further includes depositing the material of the first liner layer to a thickness of about 3 nanometers to about 10 nanometers,
depositing the barrier layer on or over the first liner layer further includes depositing the material of the barrier layer to a thickness of about 1 nanometer to about 2 nanometers, and
depositing the second liner layer on or over the barrier layer further includes depositing the material of the second liner layer to a thickness of about 3 nanometers to about 10 nanometers.

10. The method of manufacture of claim 1 wherein:
the first liner layer is a silicon oxide material,
the barrier layer is a silicon nitride material having a thickness of less than 3 nanometers, and
the second liner layer is a silicon nitride material.

11. An integrated circuit device comprising:
isolation regions formed in an exposed surface of a material of, on or above a substrate, the isolation regions including:
a first liner layer;
a barrier layer disposed on or over the first liner layer, wherein the barrier layer is less than 3 nanometers in thickness and inhibits diffusion of nitrogen atoms there through;
a second liner layer disposed on or over the barrier layer, wherein the second liner layer includes a nitrogen bearing material; and
a plurality of memory cells, wherein each memory cell thereof includes at least one transistor, wherein transistors of neighboring memory cells are separated by the isolation regions.

12. The integrated circuit of claim 11 wherein the barrier layer is about 1 nanometer to about 2 nanometers in thickness.

13. The integrated circuit of claim 11 wherein the barrier layer is a nitrogen bearing material having a thickness of about 1 nanometer to about 2 nanometers.

14. The integrated circuit of claim 11 wherein the barrier layer is a nitrogen bearing material.

15. The integrated circuit of claim 11 wherein the barrier layer is a silicon bearing material.

16. The integrated circuit of claim 15 wherein the barrier layer is an amorphous silicon material.

17. The integrated circuit of claim 11 wherein:
the first liner layer is about 3 nanometers to about 10 nanometers in thickness,
the barrier layer is about 1 nanometer to about 2 nanometers in thickness, and
the second liner layer is about 3 nanometers to about 10 nanometers in thickness.

18. The integrated circuit of claim 11 wherein:
the first liner layer is a silicon oxide material,
the barrier layer is a nitrogen bearing material having a thickness of about 1 nanometer to about 2 nanometers, and
the second liner layer is a silicon nitride material.

19. A method of manufacture of a mask for use in fabrication of integrated circuits including a plurality of memory cells, wherein each memory cell thereof includes at least one transistor, wherein transistors of neighboring memory cells are separated by isolation regions, the method of manufacture of a mask comprises:
depositing a pad layer on an exposed surface of a material of or on a substrate;
depositing a barrier layer on or over the pad layer wherein the barrier layer includes a thickness of about 1 nanometer to about 2 nanometers; and
depositing a hard mask layer on or over the barrier layer, wherein the hard mask layer includes a silicon nitride material and wherein the barrier layer inhibits diffusion of nitrogen atoms there through.

20. The method of manufacture of claim 19 wherein depositing the barrier layer further includes depositing a nitrogen bearing material.

21. The method of manufacture of claim 20 wherein depositing the nitrogen bearing material includes depositing the nitrogen bearing material using atomic layer deposition.

22. The method of manufacture of claim 19 wherein depositing the barrier layer further includes depositing an amorphous silicon material.
